(19) United States
(12) Patent Application Publication
(10) Pub. No.: US 2009/0315741 A1
(43) Pub. Date: Dec. 24, 2009

(54) METHOD OF PROVIDING MORE BIGGER EFFECT OF BUTTON

(76) Inventor: KiJu Kim, Gwang-ju (KR)

Correspondence Address: SEED INTELLECTUAL PROPERTY LAW GROUP PLLC, 701 FIFTH AVE, SUITE 5400, SEATTLE, WA, 98104, US

(21) Appl. No.: 12/523,720

(22) PCT Filed: Jan. 21, 2008
(86) PCT No.: PCT/KR08/00349

§ 371 Date: Jul. 17, 2009

(30) Foreign Application Priority Data
Jan. 22, 2007 (KR) 10-2007-0007504
Feb. 13, 2007 (KR) 10-2007-0015679
Feb. 16, 2007 (KR) 10-2007-0017305
Feb. 25, 2007 (KR) 10-2007-0018771
Apr. 16, 2007 (KR) 10-2007-0036776
Apr. 27, 2007 (KR) 10-2007-0041478
May 5, 2007 (KR) 10-2007-0043821
May 5, 2007 (KR) 10-2007-0043831
May 16, 2007 (KR) 10-2007-0047835
Jun. 14, 2007 (KR) 10-2007-0058072
Sep. 13, 2007 (KR) 10-2007-0093341
Jan. 7, 2008 (KR) 10-2008-0001558

(51) Int. Cl. H03M 11/00; H01H 13/70; G06F 3/023; H04M 1/23

(52) U.S. Cl. 341/23; 200/5 R; 345/172; 341/22

(57) ABSTRACT

The present invention has to do with the method of increasing the efficiency of buttons on electric and electronic devices. To elaborate, the purpose of the invention is to enhance convenience and efficiency by improving areas of difficulty when operating buttons on computer keyboards, telephone varieties keyboards, electronic calculator keypads, etc. In terms of the method of operating all or a part of the buttons on devices that require the use of buttons, the present invention seeks to ensure a higher number of operations as well as convenient and rapid operation with a limited number of buttons by setting function buttons and letter buttons which are not combination-inducing-buttons as combination-inducing-buttons, based on a method that allows the carrying out of an operation that has been designated in advance even in a combination situation including the combination, combination sequence, or the method of hitting the button of two or more buttons that are simultaneously in the state of being switched on. (A manufacturer or non manufacturer can determine the combination or combination situation relating to operation). Since, there is a trend in recent times to combine several functions on a single device which contain the function of a cell phone, MP3, cameral, recorder, radio, etc., it can be said that the present invention's method is more urgently needed. Another prominent feature of the present invention is to help achieve the aforementioned efficiency by changing the button layout of other devices such electronic calculators, telephone varieties, or computer keyboards and by improving the operational method of the toggle keys on computer keyboards.

### TECHNICAL FIELD

The invention delineated here has to do with the method of enhancing the efficiency of electric/electronic buttons. To elaborate, the invention seeks to improve areas of inconvenience when a person uses computer keyboards, telephone variety keyboards, or electronic calculator keyboards, etc. and to increase efficiency and convenience.

### BACKGROUND ART

For the purpose of securing effective technology for this invention, it is mentioned together in the paragraph on “Best Mode”

### DISCLOSURE OF INVENTION

### Technical Problem

This invention entails the method of enhancing the efficiency of buttons on various devices when the number of buttons is less than the number of types of work to be done. The invention retains the existing press mode (short, long, double click, triple click, number of clicks, etc.) that allows for operation with just one hand but at the same time, operation is possible in accordance with the method associated with the present invention. Especially, without having to add new hardware such as a button to existing merchandise and employing the button operation method as it is, this invention provides a separate set of methods so that the user can easily perform existing operation as well as new operation. The purpose of this is to increase the multifunctional nature of the buttons, reduce work time, and increase user convenience.

### Technical Solution

This invention seeks to achieve the purpose set out above in respect to the method of enhancing the operation of all or a part of the buttons on a device that is utilized by pressing buttons on its keyboard. As such, it enables the user to achieve more work more conveniently and more quickly by using a limited number of buttons. This is done by turning a non combination-inducing-button such as the function and letter buttons into combination-inducing-buttons. This process is based the fact that pre-designated operation can be done even in a combination situation such as a combination, combination sequence, or the method of hitting the button of two or more button that are simultaneously in the state of being switched on. (designation of combination or combination situation that is related to the operation can be determined by the manufacturer or non manufacturer).

Also, even though a button is designated as a combination-inducing-button bringing on a special type of operation (e.g. allowing a person to write the second letter allocated to another button) when the button is combined with another button, it is still possible that the same type of operation is performed when the other button that induces the same type of operation as that special type of operation is combined with another button that is mentioned 4 lines above. That is, the method of securing more than two combination-inducing-buttons that bring on an identical type of operation and of securing more than one case which is designated by the manufacturer or non-manufacturer. And there,

the type of operation induced when a certain button is used as a combination-inducing-button does not change in accordance with the relationship to other buttons in terms of the spatial position.

And by proposing even the method that allows for a person to always make the same designation regardless of the relationship to other buttons in terms of the spatial position,

one can increase convenience and the speed of typing in the letters when a certain button and another button are both letter buttons and are in letter writing mode.

### ADVANTAGEOUS EFFECTS

According to the present invention as delineated above, one should enhance operational convenience in terms of the equipments that possess parts for the display and buttons. This can be achieved by ensuring that the higher the frequency of use a button shows, the closer it should be placed to the display.

That is,

in terms of the calculator, by narrowing the distance between the display part and the part for number buttons-four fundamental rules of arithmetics symbols button which reduces the scope of movement of the focus of the eye, which in turn causes less tiredness and increases convenience, one can reduce the rate of typing error and decrease work time by making verification of accounts via the display part.

In respect to the telephone variety devices, by narrowing the distance between the telephone varieties's display part and the letter buttons part, the following advantages can be secured.

First, by reducing the scope of movement of the focus of the eye, one can decrease tiredness and inconvenience, and in this way the rate of typing error is reduced. Also, work time will decrease because the user can easily verify via the display part.

Second, by holding the device in a steady manner and bending the thumb to the extent that it is not awkward, the user can hit the letter buttons in a natural fashion.

Moreover, in terms of the computer keyboard, by placing the combination-inducing-buttons in the first, second, or other rows, that is the upper part of the keyboard, one can make convenient the operating of the combination-inducing-buttons with one hand such as by pressing the buttons with fingers other than the thumb (especially the little finger) and pressing the other key with the thumb, etc. And in terms of the toggle key, by allocating mode alteration signal of different signals for each mode allocated to the toggle key, the user can firmly make mode change according to one's wishes.

Hence, because of this, there is no error in operation even though the user gives alteration signal of desired mode in order to change to the desired mode by misunderstanding that the present mode is different from the mode that one wants even though they are identical. Also, if it is thought that judgment about the present mode is uncertain, then the user can in the first instance give the alteration signal to the mode that he or she wants and continue with the operation. As such, it can be considered that in reality, the lamps and other mode verifying devices are not necessary and thus, a user who knows by heart the keyboard layout does not need to perform a movement during an operation to verify the mode.

Furthermore, in terms of operating the buttons of electronic devices including telephone varieties, and especially in regards to the letter input method of the present invention, one can make mention of several strengths which will be referred to later.

1. When considering the greatest strength, it can be seen that the user can independently utilize the present invention's method all the while using other letter input methods simultaneously with this invention's method without altering the letter input mode in other letter input modes (multi tab, ‘T9 and others’ various Korean input method (Samsung's Cheonjiin, LG Electronics' EZ, and other input method for various languages). During this process, there are features such as maximizing the efficiency of other letter input methods as well as coexisting and harmonizing with those other methods without excluding them. As such, there are no risks involved in applying this invention's method.

Especially, the greatest weakness found in methods like the ‘T9 and others’ which make it difficult to choose a word from among the many candidate words that are suggested and like the need to enter a word when the DB does not have a word the user wants by changing the letter input mode before entering have been innovatively dealt with. In other words, because in the letter input mode such as the ‘T9 and others’, the user can type in the confirmed letter, unknown letter, or special character within two typings without having to alter the letter input mode, he or she can drastically reduce the number of candidate words by simply typing as a confirmed letter just one spelling among the search words. Also, minimizing the time for entering the search words is possible by using unknown letters, and even for words not found in the DB, one can directly type in all spellings as confirmed letters without mode alteration in the letter input mode such as the ‘T9 and others’.

This is why it is possible to enter easily ideograms such as Chinese characters.

In the multi tab mode as well, one can employ the multi tab mode as it is and still type all letters with two typing inputs or less by utilizing the present method. And one can remove the need to wait for two seconds or hit the right arrow button for the purpose of verifying the prior letter when consecutively typing the letter allocated to the same button.

2. Even if a total of ninety letters were allocated by giving nine letters to the ten buttons, 0˜9, one can directly enter the first letter in a single typing action, and the rest of the letters can easily be typed in by double clicking or in two typing combination made up of single typings (It is not necessary to press for an extended time).

When entering a certain phoneme, three typings or more or an extended hit time radically increases the sense of inconvenience in comparison to 2 typings, but this can be resolved.

Because of this, when using Korean letters, all phonemes can be entered within two typings by allocating all forty Korean phonemes. So far, for Korean, phrases have been generally typed by making complex phonemes of 3˜5 typing hits by combining complex phonemes with simple phonemes, and the set pattern of thinking insisting on this process can be changed. However, by additionally allocating in a completed format only those phonemes that are possible to be created in 3˜5 typing hits in the existing method of inputting Korea, the existing method could be used as it is, and the present invention's method can be simultaneously operated in a symbiotic manner.

Of course, this is also possible for languages with more letters like Japanese (50), Hindi (46), and That (56).

For this reason, the user can easily make the input even in the multi tab mode by applying the present method for languages like Korean or Japanese to which it is difficult to apply the letter input method such as the “T9 and others” because of the many wording changes.

Approximately 20˜30 frequently used special letters can be allocated in the buttons right next to the ordinary letters, and this makes it possible to type in within two typings in the ordinary letter mode without changing the mode.

It is expected that this will possess the highest speed among letter input modes for small keypads like those on a cell phone.

3. This can minimize the scope of finger movement as well as the fingers getting in each other's way.

4. Although there are good advantages when applied to the qwerty keyboards, it can also be seen that it is indispensable for medium and low priced devices that have small keypads which are not qwerty keyboards.

This is because it approaches very closely to the letter input speed of the qwerty keyboards.

5. There are other various advantages.

### BRIEF DESCRIPTION OF THE DRAWINGS

FIG. 1 shows the approximate layout of buttons on existing cell phone.

FIGS. 2 and 3 show a table of several combinations among the many possible combinations that could become any of the buttons 1 to 4 as based on the present invention.

FIGS. 4 and 5 exhibit a table of several combinations among the many possible combinations that could become any of the buttons 1 to 6 as based on the present invention.

FIGS. 6 and 7 display a table of several combinations among the many possible combinations that could become any of the buttons 1 to 8 as based on the present invention.

FIG. 8 is a plan for the hitherto display and button parts.

FIG. 9 is a plan for the approximate display and button parts of a calculator that has applied the present invention's method.

FIG. 10 shows the plan for the approximate display and button parts of cell phones made so far.

FIG. 11 is a plan showing the approximate display and button parts of a cell phone applying the present invention's method.

FIG. 12 shows a chart displaying an ordinary existing keyboard.

FIG. 13 is a plan that shows the letter button part that has been moved to the right and which is one of the good examples of applying the present invention.

### BEST MODE FOR CARRYING OUT THE INVENTION

In what follows, a detailed explanation of how the present invention enhances the efficiency of electric/electronic buttons will be given.

This application provides in an organized form the proposal for improvement in the following four areas for the purpose of dealing with inconveniences associated with operating buttons on computer keyboards, telephone variety keyboards, electronic caculator keypads, etc. so as to enhance efficiency and user friendliness.

First, the calculator and telephone varieties button with high frequency of use have been placed near the display part.

Second, the combination-inducing-button of the computer keyboard have been placed on the upper part.

Third, the operational method for the computer toggle key has been improved.

Fourth, new work is created via the combination of other buttons on electronic devices (Especially, emphasis has been placed on the letter input method).

In the continued explanation below, the above first, second, third, or fourth item will be expressed sequentially as AAA part, BBB part, CCC part, and DDD part.

To facilitate clearer understanding, the background art as well as the configuration and effectiveness of the present invention will be described by comparing with existing technology.

The terminology of the first improvement proposal (hereafter, ‘AAA Part’) mentioned above will be defined as follows.

First, the example of the calculator,

1. Display part: An ordinary LCD belongs to the display part.

2. Number buttons part: The sector to which the buttons for numbers 0˜9 are placed.

3. The part for the buttons for the symbols of the four rules of arithmetics: The section where one finds the buttons for addition, subtraction, multiplication, division, and ENTER (=equal).

4. The part for number buttons-buttons for the symbols of the four rules of arithmetics: A terminology that jointly refers to the number buttons part and buttons for the symbols of the four rules of arithmetics.

5. Other button part: The sector where buttons other than the number buttons and four rules of arithmetics buttons such as the function buttons, mathematical function buttons, etc. are located.

6. Buttons part: The sector where the types of button that are similar in characteristics such as the number buttons—buttons for the symbols of four rules of arithmetics or other button parts are located.

7. Button parts: All sectors other than the display part where buttons are situated.

Also, with the telephone varieties as an example,

1. Display part: An ordinary LCD belongs to the display part.

2. Letters: A word that comprehensively refers to phrases, numbers, symbols, etc.

3. Function: The capacity to perform an operation other than the letter displaying operation.

5. Letter buttons part: A section where the buttons that write letters are located (The sector where ordinarily twelve buttons with the 0˜9, *, and # constituting the representative letters are found).

6. Function buttons part: The section where buttons that are used to carry out operations other than those operations that have to do with writing letters are located.

7. Buttons part: The section where types of buttons such as the letter buttons part or function buttons part that are similar in characteristics are located.

8. Buttons part: All sections other than the display part, that is the area where the buttons are situated.

9. Telephone varieties: A terminology that comprehensively refers to the telephones for home use, cell phone, PDA, etc.

The terminology for the abovementioned second proposal for improvement (hereafter, ‘BBB Part’) will be defined as follows.

1. Combination-inducing-button: This refers to keys such as the Shift, Ctrl, Alt, etc. which cannot perform a function on its own but can do so only in combination with other keys. Most of the time, these keys carry out a function when it is pressed at the same time as other keys. For example, if one hits button P while the Ctrl key is pressed, the print menu will pop up. As such, many menus of a software program can be utilized for the most part with shortcut keys that necessitate a combination-inducing-button. An ordinary keyboard has a set of Shift, Ctrl, and Alt keys on its either side.

2. Left combination-inducing-button: This is located to the left of the keyboard and is placed there as a combination-inducing-button.

3. Right combination-inducing-button: This is located to the right of the keyboard and is placed there as a combination-inducing-button.

4. Operation of a combination-inducing-button: This refers to hitting the combination-inducing-button with another key when wishing to perform a command using the combination-inducing-button.

5. Other than the thumb: This refers comprehensively to all fingers excluding the thumb such as the little finger, ring finger, middle finger, and index finger.

The terminology for the abovemention third proposal for improvement (hereafter, ‘CCC Part’) is defined as follows.

1. Letter: This refers comprehensively to character, numbers, symbols, space, etc.

2. Toggle Key: This refers to a single key which has a function that allows two or more mode conversion or other similar functions.

E.g.) Letter mode conversion keys such as the Korean/English Key (Conversion key for Korean and English) and other similar keys.

CAPS LOCK Key: Mode conversion key for English capital and small letter

NUM LOCK Key: This refers to the conversion key for number mode and direction mode when hitting the keys in the separate 3 rows/3 columns number pad located on the righthand corner of the keyboard.

SCROLL LOCK Key: This refers to the conversion key for setting and canceling the scroll function.

INSERT Key: This refers to the conversion key for insert and revise when typing in letters.

3. Press method: The method of pressing a key.

E.g.) single hit: A short press of the button on the keyboard.

Double click: This refers to hitting the button quickly and twice in a continuous manner.

Triple click: This refers to hitting the button quickly and thrice in a continuous manner.

Long hit: This refers to pressing the button for an extended time (approximately more than one second).

4. Simultaneously hitting the A and B keys: The method of hitting the B key while pressing the A key.

5. ON: The point of contact is maintained

6. OFF: The point of contact is detached.

7. Combination Situation: This refers to the situation which entails whether a given key performs an operation on its own or is in combination with another key as well as the sequence of switching on when in combination, the method of pressing the keys, etc.

8. Combination-inducing-button: This refers to buttons such as the Ctrl, Alt, Shift, etc. keys that induce combination with other keys.

9. Mode verification device: This refers to the devices such as a lamp which indicate the state of the present mode.

The terminology for the abovementioned fourth proposal for improvement (hereafter, ‘DDD Part’) are defined as follows.

1. ON: The point of contact is maintained.

2. OFF: The point of contact is detached.

3. Letters: This refers comprehensively to characters, numbers, symbols, etc.

4. Function: This refers to the capacity for continuing with an operation (Depending on the situation, this can also refer to the capacity for continuing with an operation that excludes the letter displaying operation).

5. Letter button: This refers to the buttons that allows for the writing of letters when it is switched on or to the twelve buttons made up of 0˜9, *, and #.

6. Function button: This refers to the button that allows one to carry out an operation other than the letter writing operation.

7. Combination-inducing-button: After this has been switched on and before it is switched off (or after it has been turned OFF), the button performs a certain operation based on a combination with another button switched on, or after another button has been switched on and before it is switched off (or after it has been switched off), the button performs a certain operation based on a combination with itself switched on.

In other words, this means that operating the combination-inducing-button beforehand or afterward is decided voluntarily by the manufacturer or non manufacturer.

And of course, this is a button that does a certain operation when only itself is switched on (or after it has been switched off). That is, there are instances where one can speak of it becoming a combination-inducing-button based on the present invention's method even though it was not a combination-inducing-button in existing methods.

Besides these situations, the term refers inclusively to buttons that will possess the function to induce a “combination” situation, as mentioned in no. 19.

8. A button that exclusively functions as combination inducing entity (Shift button types): This refers to the button that cannot perform any operation on its own, such as the combination-inducing-button like the Shift button, Ctrl button, Alt button, etc.

9. Button+Number (E.g.: “Button 3”: This refers to the button to which is allocated number 3 or means that one presses the button to which is allocated number 3).

10. Press method: It refers to short, long, double click, triple click, press frequency, etc.

11. Combination situation: This refers to a button operating independently or in combination with other keys, the sequence of switching on when combining, the method of hitting the buttons, etc.

12. Operation: This refers to all situations where there are changes to the device. For example, the movement of the cursor and the writing of letters are included in the operation.

13. The combination of buttons for which a particular operation is predetermined: This can be a shortcut key for an existing operation or a combination for a new operation.

14. Existing methods of button operation: This denotes the position of each button, and the letter allocated to each button, and button combination, etc. in existing products that are necessary for the operation which the user intends to perform, and it is a method that does not take into account the on and off control of the buttons that relate to the present invention.

15. “T9 and others”: This refers comprehensively to an existing method which provides the user with more than one word that is possible to be formed via the combination of the spellings allocated to the ON buttons by utilizing the word DB, even when the input is made without fully determining the exact spelling and allows the user to make a selection from among the choices.

For example and to explain further, this is a method of typing in a letter wherein even when multiple letters are attributed to one button which forms one among many methods of inputting letters, if one were to enter the spelling with candidate letters for which the spelling is not confirmed and in accordance with the method of single hitting of the key and other such methods, and when the device suggests to the user more than one word that is possible to be formed based on the typed spelling, the user selects the word which contains the spelling sought after by him/her. This method is called different name according to the cell phone manufacturer such as “T9 mode” in SAMSUNG, “iTAP mode” in MOTOROLA, “PREDICTIVE TEXT INPUT mode” in NOKIA.

For instance, in terms of the T9 method, since if the ‘4663’ button is pressed then ‘GHI’ is allocated to ‘4’, ‘MNO’ is allocated to ‘6’, and ‘DEF’ is allocated to ‘3’, when the device searches their combination in the dictionary database and then suggests ‘GONE’, ‘HOME’, ‘HOOD”, ‘HOOF’, ‘HONE, and ‘GOOF’ in accordance with the frequency of use, the user selects the desired word by placing a cursor over it.

16. Confirmed letter: To improve the letter input methods such as the “T9 and others”, the present invention uses the method of letter input based on the verification of spelling in the letter input methods such as the “T9 and others”.

17. Candidate letter: Similar to existing input methods such as the “T9 and others”, this refers to the several letters that are allocated to that button which has been switched on. When the above button 4 is turned on, ‘G’, ‘H’, and ‘I’ become candidate letters.

18. Unknown letters: To improve letter input methods such as the “T9 and others” and as employed in the present invention, ‘*’ or ‘?’ are used for the most part when a search is made on the computer and are letters all of which can become candidate letters as having been allocated to all of the letter buttons. It can also be prescribed that one unknown letter could replace another which has two or more consecutive letters.

19 Combination: Until now, it may seem that combination referred to the situation where two buttons are simultaneously switched on, but it also includes a recognition of combination if the time of the button that have already been switched on being switched off and the time of the button that is subsequently switched on being switched on are within a fixed time frame. This is to deal with the difficulty associated with switching on two buttons sequentially and then switching them off simultaneously in a continuous manner, which can arise when the combination button is frequently used and the user is not fully adept. At this stage, if one seeks to type in two letters by switching two buttons on and off, that is to employ the two buttons as letter buttons, one must first operate the time interval between the time of the button that has been switched ON first being switched OFF and the time of the button that has been switched ON later being turned ON at a greater than the fixed time interval.

And, in the letter writing mode that includes the volume control button or internet connection button, when the button that does not respond after being switched on is designated as a combination-inducing-button, and if there is no situation where the combination-inducing-button and the combination partner button are simultaneously switched on and if there is no limit to the time interval between the time of the button that has been switched on first being switched off and the time of the button that has been switched on later being turned on, it is also considered as a combination between the buttons.

20. Alphabet: This refers to phonemes of the entire phonetic symbols such as the English alphabet, European letters that are similar to it or to Korean letters or others, however, it is sometimes used to refer to all letters.

21. Button: This refers not only to concrete buttons but also to all of non concrete buttons such as the touchpad and laser pad, etc.

22. character: This refers comprehensively to the letters that are not symbols or numbers, such as alphabets, Korean and Japanese letters, Chinese characters, etc., but there are times when it refers to all letters including symbols and numbers as in everyday usage.

To explain in detail about the AAA part referred to above,

In respect to the device that has a display part and button parts, between the buttons part that has a high frequency of use among the button parts and display part, there exists the buttons part that have a low frequency of use. Because of this, in the repeated process of pressing the buttons and verifying the display part, the scope of movement of the focal point of the eye widens causing inconvenience, and one becomes tired, readily causing typing errors. Also, work time extends longer than usual because making verification via the display part becomes difficult.

When one looks at a calculator as an example,

To classify broadly three constituent components in order to explain the present invention's method for the part that appears externally in existing calculators, there are first, the display part, second, the part for the number buttons-buttons for the symbols of the four rules of arithmetics, and third, the miscellaneous buttons part. In using a calculator, the frequency of use of the number buttons-buttons for the symbols of the four rules of arithmetics is much higher than for the miscellaneous buttons part. As such, the eye focuses a lot on the part of the number buttons-buttons for the symbols of the four rules of arithmetics and on the display part which shows the typed content. However, when one looks at the placement of each constituent component in existing calculators, the display part is located in the upper part, the miscellaneous buttons part located in the center, and the part for the number buttons-buttons for the symbols of the four rules of arithmetics located in the lower area. As such, the focus of the eye often covers over a large area including from top to bottom. This is why the user can easily feel tired and typing errors are made due to inconvenience, and work time extends longer than usual because checking figures and verification via the display part are difficult.

Moreover, taking telephone varieties as an example,

To classify broadly three constituent components in order to explain the present invention's method for the part that appears externally in existing telephone varieties, there are first, the display part, second, the letter buttons part, and third, the function buttons part.

First, in using telephone varieties, the frequency of use for the letter buttons part is much higher than for the function buttons part.

Thus, much attention is paid to the letter buttons part and the display part, which displays the typed content. However, when looking at the placement of each constituent component in existing telephone varieties, the display part is located in the upper area, the function buttons part in the center, and the letter buttons part in the lower area. As such, the focus of the eye often covers over a large area including from top to bottom.

That is why the user can easily feel tired and typing errors are made due to inconvenience, and work time extends longer than usual because checking figures and verification via the display part are difficult.

Second, in terms of holding the telephone varieties and pressing the letter buttons with one hand simultaneously, because the letter buttons part is located in the lower area, to press the buttons part with the thumb, one has to hold the lower part of the telephone varieties in an unsteady manner or to hold the telephone in the center area, one has to bend the thumb downwards drastically in order to hit the buttons.

Holding only the lower part denotes the continuation of a situation where only a part of the device is held, and this lowers stability and raises concern for dropping the device. And there are instances where the devices have actually been dropped. Yet, to hold the center area of the device so as to press the letter buttons part is often to make the user drastically bend his/her thumb and continues to lower the level of stability in terms of holding the device longer. This in turn makes it that much more inconvenient to use the lower buttons found in the letter buttons part. Ultimately, it is most inconvenient to use the buttons to which “*, #, and 0” are allocated.

To explain the means of solving the problems linked with the AAA part mentioned above,

In regards to the devices with the display part and buttons parts, a plausible method is to make a placement so that the higher the frequency of use is for a given button, the closer it will be placed to the display part.

A. A Calculator as an Example

It is proposed here that existing problems can be solved by narrowing the distance between the display part and the part for the number buttons-buttons for the symbols of the four rules of arithmetics that have high frequency of use. As such, one can successfully deal with existing problems by giving an example of placing the display part in the upper section, the part for the number buttons-buttons for the symbols of the four rules of arithmetics in the center area, and miscellaneous buttons part in the lower section.

B. Telephone Varieties as an Example

By placing the display part close to the letter buttons part with a high frequency of use and by excluding the method of placing the letter buttons part below the device, this invention intends to find a solution to the problems that have hitherto existed.

In this respect, one can solve existing problems by considering as an example the placing of the display part in the upper area, the letter buttons part in the center, and the function buttons part in the lower area.

To explain in detail the above BBB part,

When using the computer keyboard, two or more keys need to be used if one wants to operate with the combination-inducing-button.

If a person uses his or her two hands to press one key each, there would not be a problem, but in cases where one hand cannot be used including when it is holding the mouse or where the person wants to use only one hand, there arises inconvenience because the combination-inducing-button is located in the lower part of the keyboard. The reason that there is such an inconvenience is because the location of the combination-inducing-button does not take ergonomic design into account.

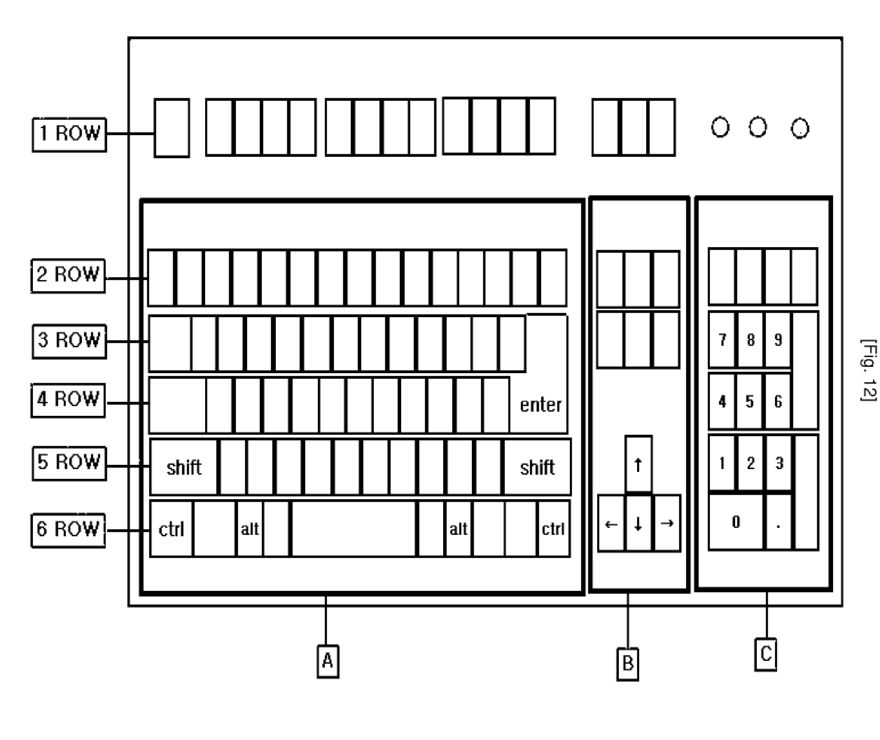

If one spreads out the fingers above the keyboard in order to press the buttons, all of the fingers except the thumb are situated away from the chest. As can be seen in FIG. 12, this means that the fingers excluding the thumb are close to row 1 while the end part of the thumb is close to row 6.

So, it is convenient to hit the space key in row 6 with the thumb. The reason for this is because the end part of the thumb hovers over row six, and it is easy for it to press the space key.

However, in existing keyboards, the combination-inducing-button is in row 5 (Shift key) or row 6 (Ctrl or Alt key). So, if a person seeks to perform an operation with the combination-inducing-button with one hand, broadly speaking, two or more problems as described below will occur.

First, in terms of the problem linked with conducting an operation for combination-inducing-button with the combination-inducing-button located on the left side of the keyboard, to press another key with a finger other than the left thumb while pressing the combination-inducing-button with the left thumb, one must turn the wrist or other parts at a very awkward angle. When the combination-inducing-button is pressed with the right thumb while trying to hit another key with a finger other than the right thumb, as soon as the combination-inducing-button is pressed with the right thumb, the left portion of the keyboard is hidden under the back of the hand. In effect, it is impossible to hit another key with the left thumb while pressing the combination-inducing-button with a left hand finger other than the thumb. One can hit another key with the left index finger in a very awkward way while pressing the combination-inducing-button with the left little finger, and it is impossible to hit another key with the right thumb while pressing the combination-inducing-button with a right hand finger other than the thumb.

Second, as a problem associated with trying to operate a combination-inducing-button with a combination-inducing-button found on the right side of the keyboard, one can reverse the words, ‘right’ and ‘left’ as used in the preceding paragraph.

To explain the method of resolving the problems found in the BBB part as mentioned above,

This is a method that allows, among others, one to operate conveniently the combination-inducing-button with just one hand. It involves pressing the combination-inducing-button with a finger other than the thumb (especially the little finger) and pressing another key with the thumb, having placed the combination-inducing-button on the first row, second row, etc. of the keyboard that is, its the upper part.

Moreover, as in FIG. 12, if the button layout of the keyboard, which is used widely in existing computer keyboards and especially those used for desktop computers, can be classified and named as A (letter buttons part), B (direction buttons part), and C (supplementary number buttons part) for the purpose of the explanation given below, since the letter buttons located within the central area of the rectangular boundary of part “A” is found only in part “A”, the distance which the right hand has to move to get to the mouse being used and that is placed on the right side of the keyboard after typing in letters is quite substantial. This is because most people are right handed.

That is, the layout of existing keyboards has been configured without taking the mouse into account, and in the present situation where a mouse is widely used, it should be considered as a device for left handed people.

The reason is because if the user is right handed, the load on the right hand operation is much greater than for the left hand when considering the layout of existing keyboards. The left hand needs only to be responsible for a small number of combination-inducing-buttons and function buttons as well as letter buttons for which it is responsible, but the right hand has to operate the buttons found in part “B” and “C” of FIG. 12 and even the mouse in addition to the same type of operation performed by the left hand.

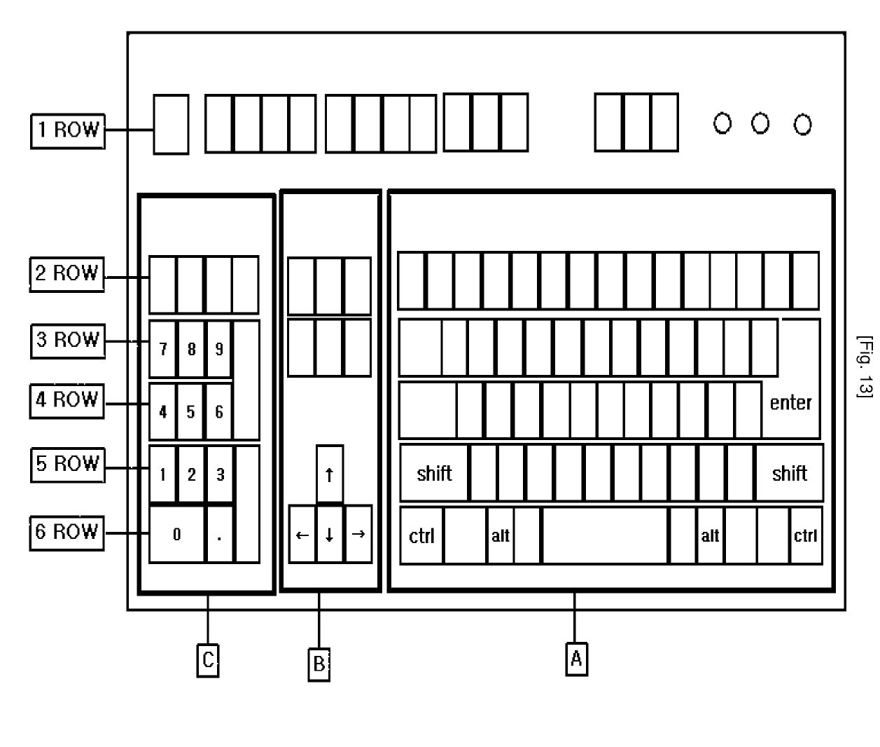

That is why the position of the letter buttons has thus far been part “A”, but in the present application, it is proposed that if a shift is made to another area including part “B” or “C”, the difference in workload between the two hands could be significantly reduced. It is also proposed here that in actual manufacturing of goods, it may be better aesthetically and for work purposes to move not just the letter buttons but as shown in FIG. 13, to have all of the buttons located within the rectangular boundary of part “A” change places with the buttons belonging to part “B” or “C”. In other words, the layout hitherto has been in the ABC sequence as shown in FIG. 12, but by applying the present invention's method, it is better to change the arrangement to the sequence of BAC, CAB, BCA, or CBA. It can be viewed that the sequence of BCA or CBA is more advisable than the BAC or CAB sequence. If this were adopted, when there is an operation with the buttons or mouse in parts “B” or “C”, it would be convenient to perform the button operations of parts “B” and “C” with the left hand and the mouse operations with the right hand. This kind of load distribution is not easy to achieve in existing keyboards.

To explain in detail the abovementioned CCC part,

In terms of the operational method of the toggle key among the keys on the computer, telephone, cell phone, PDA, etc. keyboards, the existing mode changing signal is identical (it seems to rely on a single press). As such, even after giving the mode changing signal, many are not certain whether or not the mode has shifted to the one that was sought after. That is why there arises many occasions where the user has to verify the present mode by checking whether or not the lamp, such as the NUM LOCK lamp, CAPS LOCK lamp, and SCROLL LOCK lamp which correspond to the NUM LOCK key, CAPS LOCK key, and SCROLL LOCK key found on the keyboard, is turned on or off. And corresponding to the Korean/English key, there often arises the need to verify on the monitor the letter mode indicators such as “□(KOR)” or others if the present letter mode is Korean and “A” or others if it is in the English mode. Even with such mode verifying devices, there are many occasions where the user finds the need to change mode to the sought after mode and redo the operation, since he has made a mistake because the desired mode is different from the actual mode. The reason for this is because the user mistakenly believes that he or she has accurately judged the present mode even though he or she in fact has not and, without confirming via the mode verifying device, continues with the operation in the wrong mode or especially, continues the operation by changing to a wrong mode with a single hit. This is the most frequent form of faulty operation, and as such, even if there are verifying devices, one cannot not carry out the mode changing operation 100% accurately. When the option for toolbar auto hide on the toolbar menu in the desktop is selected in order to maximize constantly the current window and where the current program window is maximized, the tool bar disappears and as such, the letter mode indicated on the toolbar naturally cannot be seen. Thus, in the toolbar auto hide mode, when the current window is maximized and then a website is opened and work is carried out, one cannot always know what the letter mode is. Also, in certain programs like the memo pad, the program itself does not indicate the letter mode, making it impossible to confirm the letter mode. So, even though the judgment on the present letter mode is uncertain, moving the pointer to the lower part of the screen to display briefly the toolbar to verify the letter mode is cumbersome, and instead by deciding that the current letter mode is the one that one wants, and without verifying the letter mode, typed in the letters, but because the letter mode was unfortunately not what the person had wanted, there are many cases where error occurs. Furthermore, when joining as member at a website and entering the ID or password, the letter mode is set in Korean and thus an error message appears. Thus, much labor goes into typing once again in an English mode. Although it needs to be typed in English small letters, because the present letter mode is set in English capital letters, there appears an error message and much labor accompanies that task of retyping after changing the mode to English small letters. I remember when joining as member at a website where it was possible to type while set at English capital letters mode. I had intended to use English small letters for the ID or password but because the letter mode at the time was set at English capital letters, the entry was made inaccurately in capital letters and I found myself perplexed later on when I could not login with small letters. Whatever the case may be, in all cases of operating the keyboard, including working with a word processor or surfing the net, errors mentioned earlier occur quite frequently and the result is an increase in work hours and a rise in stress level.

To explain the method of resolving the problem of part CCC mentioned above,

The above described errors that currently exist have arisen due to emittance of the mode alteration signal only by the same signal (usually a single hit). As a means of dealing with this problem, a method of giving a different mode alteration signal for each mode is suggested here. On in this way can one with certainty change the mode in accordance with one's wishes. Hence, if a person thinks that one's judgment about the current mode is uncertain, the person can continue with the operation after having given the signal of the sought after mode. So, it can be said that the devices for mode verification like the lamp is in effect unnecessary. Only in the case where a clear recognition of the matching of the mode alteration signals that differ from each other with a particular mode or where one needs to verify the current mode after having given the mode alteration signal can it be considered that the verification device is needed.

From now on, let us find out about the method of giving other signals.

The first concerns the method of allocating different keys per mode instead of the existing one toggle key.

For example,

Instead of the Korean/English toggle key, allocating a letter mode key for each letter type instead of a mode alteration toggle key such as having a Korean mode key and an English mode key separately, or

Allocating separately the English capital letter mode key and the English small letter mode key instead of the CAPS LOCK toggle key, or

Allocating separately the number mode key and the direction mode key instead of the NUM LOCK toggle key, or

Allocating separately the scroll function setting mode key and the scroll function resetting mode key instead of the SCROLL LOCK toggle key, or

Allocating separately the insert mode key and revise mode key instead of the INSERT toggle key or such similar methods.

Second, a method of allocating press methods that are different from each other such as the single hit, double click, triple click, long press, etc., while leaving the existing toggle key as it is.

For example,

Allocating different press methods for each letter type in the letter mode conversion toggle key including attributing the Korean language mode for a single hit and the English mode for a double click in reference to the Korean/English toggle key, or

Allocating English small letters for a single hit and English capital letters for a double click in respect to the CAPS LOCK toggle key or,

Allocating the number mode for a single hit and the direction mode for a double click in reference to the NUM LOCK toggle key or,

Allocating the scroll function setting mode for a single hit and the scroll function resetting mode for a double click in reference to the SCROLL LOCK toggle key, or

Allocating the insert mode for a single hit and the revise mode for a double click in respect to the INSERT toggle key or such similar methods.

Third, a method of leaving the existing toggle keys as they are but at the same time allocating the combination of the toggle key with other keys for each mode.

A. A method of pressing a combination-inducing-button like the Shift, Ctrl, Alt, etc. keys and simultaneously hitting a toggle key.

For example,

Allocating a single hit of the Korean/English toggle key as Korean mode and the simultaneous press of the Shift key and the Korean/English toggle key as English mode, which is an example of assigning separately a single hit of the letter mode conversion toggle key or a simultaneous pressing method for the combination-inducing-button and letter conversion toggle key for each letter type in reference to the letter conversion toggle key or,

Allocating English small letters for a single hit of the CAPS LOCK toggle key and English capital letters for a simultaneous use of the Shift key and the Korean/English toggle key, or

Assigning the number mode for a single hit of the NUM LOCK toggle key and the direction mode for a simultaneous use of the Shift and NUM LOCK toggle keys, or

Allocating the scroll function setting mode for a single hit of the SCROLL LOCK toggle key and the scroll function resetting mode for the simultaneous use of the Shift and SCROLL LOCK toggle keys, or

Methods that include assigning the insert mode for a single hit of the INSERT toggle key and the revise mode for a simultaneous use of the Shift and INSERT toggle key.

B. A method of simultaneously using the toggle key and any other keys chosen randomly (or a particular key).

A method of hitting the toggle key alone or of simultaneously using the toggle key along with any other keys chosen randomly (or a particular key). In such a case, the signal given by the toggle key must be determined not by the method of confirmation when the toggle key is switched on but by the combination situation with another key until it is switched off.

For example,

Assigning Korean mode to a single hit of the Korean/English toggle key and English mode to the simultaneous use of the Korean/English toggle key and any other keys selected randomly (or a particular key), which offers an example of the method of allocating separately a single hit of the letter mode conversion toggle key or a simultaneous use of letter conversion toggle key and any other keys chosen randomly (or a particular key) for each letter type in reference to the letter mode conversion toggle key or,

Allocating English small letters to a single hit of the CAPS LOCK toggle key and English capital letters to the simultaneous use of the CAPS LOCK toggle key and any other keys used randomly (or a particular key), or

Assigning the number mode to a single hit of the NUM LOCK toggle key and the direction mode for a simultaneous use of the NUM LOCK toggle key and all other keys used randomly (or a particular key), or

Allocating the scroll function setting mode for a single hit of the SCROLL LOCK toggle key and the scroll function resetting mode for a simultaneous use of the SCROLL LOCK toggle key and any other keys hit randomly (or a particular key), or

Methods that include assigning the insert mode for a single hit of the INSERT toggle key and the revise mode for a simultaneous use of the INSERT toggle key and any other keys hit randomly (or a particular key).

Fourth, a method of allocating voice commands that differ from each other per mode via the voice recognition device.

Fifth, assigning physical movements that differ from each other per mode via the movement recognition device that recognizes movement by detecting physical variation.

For example, one can assign the native language to the movement of sticking out the tongue and English language to the movement of biting the lower lip.

Sixth, a method of indicating the mode of each toggle key via switching on and off of a light by putting in place an indicating lamp.

To explain in detail the abovementioned DDD part.

The purpose of this is as follows. Since this part has to do with the method of enhancing the button efficiency of equipments that have fewer buttons than the number of operation types, while maintaining the press method of existing buttons that enable the user to operate with a single hand (short, long, double click, triple click, press frequency, etc.), the operation is also carried out based on the present invention's method. Since, without having to add any new hardware parts such as buttons to the existing device and by adding almost only programs so that the existing button operation method remains intact but a separate method is provided, the existing operation can be performed easily and new operations can also be conducted. In this way, the multi functional capability of the buttons is increased, work time is reduced, and convenience is enhanced.

Based on the method of the present invention, even if it is a function button or a letter button that is not a combination-inducing-button, it can act as a combination inducing button in addition to its original function. That is, whatever the button may be, it can be converted to a combination-inducing-button, and as such, the distinction between a combination-inducing-button, function button, and letter button disappears.

In what follows, a specific example will be given to provide an explanation.

(The reason that the computer is taken as an example is to explain that this invention is applicable to existing computers, that is to show that it is an original method not found even in computers and not to claim that its effect even in existing computers is large.

To look at a computer first, until now, even if it is a computer keyboard with a relatively high number of buttons, separate Shift, Ctrl, Alt, or other such combination-inducing-buttons must first be switched on in order for a combination with other buttons can take place and for the next operation to commence.

First, by designating a certain operation with a shortcut key, that operation is performed easily (E.g., To copy a computer screen as it is, one uses the Alt key in combination with the print screen button, and a shortcut key is formed for the print command by combining the Ctrl button with the button to which is assigned “P”).

Hereafter, as “a combination of buttons to which is designated a special operation in advance”, an expression with a larger scope is used.

Second, a particular operation is realized only while the combination-inducing-button is turned on and is combined with the button that is switched on subsequently (E.g., When trying to type “□” in Korean mode, one must use the Shift key and the button to which is assigned “□”).

In terms of the existing problems described above, without relying on the combination with the button that specializes only on inducing a combination and one hits the function or letter button, it always operates a certain function or displays letters, which means that before a certain function button or letter button is switched off after having been switched on, if another button is turned on, a new operation other than the original function or letter writing cannot be carried out with such a combination.

To look at an application in the present invention,

First, the explanation shall be given under the assumption that, as a process “a”, a function identical to the Shift key is given to button “S” besides its original function, a function identical to the Ctrl key is given to the button “C” in addition to its original function, and a function identical to the Alt key is given to button “A” besides its original function.

(In the explanation that is approximately 2 page in length given below, as explained only with the process “a” as a condition, the above condition that is,

instead of the button to which the letter “S” is assigned, all of the buttons belonging to part “A” of FIG. 12,

instead of the button to which the letter “C” is assigned, all of the buttons belonging to part “B” of FIG. 12,

instead of the button to which letter “A” is allocated, all of the buttons belonging to part “C” of FIG. 12 are substituted, and ultimately this allows one to do away with the Ctrl, Shift, and Alt keys that exclusively function as combination inducing parts, and because the number of buttons that possess functions that are identical to those of combination inducing specialist buttons increases, when performing an operation where the user has to use a combination inducing specialist button without looking at the keyboard, the probability of error in operation can be brought down to almost zero.

Until the abovementioned button to which is allocated “S” is switched off after being switched on, if another letter button is not turned on and if a button that is not a button which carries out a combination to which another operation is specified is switched on, the letters of a button to which is allocated S that is appropriate to the present letter mode are displayed and if another letter button is switched on, it is possible to make the button perform a function identical to the Shift key. (E.g., After switching on the button to which is assigned “S” (“□” is assigned in Korean language) and then is turned off, if the button to which “P” is allocated (For Korean language, to the lower case, “□” is allocated and to the letter corresponding to the Shift key, “□” is allocated) is switched on, then “□” is written, and before switching off the button to which “S” is allocated after it has been turned on, if the button to which is assigned “P” (For Korean language, to the lower case letter, “□” is allocated and to the letter corresponding to the Shift key, “□” is allocated) is turned on, then only “□” which is not a complete letter is displayed. (If one were to apply the method of operating a combination-inducing-button after operating a combination object button, until before the button to which “P” is allocated (For Korean language, to the lower case letter, “□” is assigned and to the letter corresponding to the Shift key, “□” is assigned) is turned off after having been switched on, if the button to which is allocated “S” (For Korean language, “□” is allocated) is switched on, “□” is displayed, and if the button to which “P” is assigned is turned off and the button to which is allocated “S” is switched on, then “□” (lower case) and “□” is displayed.)

Moreover, as a process of “b”, if one were to apply by expansion the assumptions of aforementioned “a”, it may be possible to add a new concept combination-inducing-button function to the existing letter buttons without having to create new keyboard buttons.

For example, until before the button to which is assigned “S”, “C”, or “A” is switched off after having been switched on, if button that has been pre-designated to perform a predetermined operation other than letter display when the Shift, Ctrl, or Alt keys are combined with the button is turned on, the predetermined operation is carried out (If one were to apply the method of operating the combination-inducing-button after the combination object button, until before the button that has been pre-designated to perform a predetermined operation other than letter display when the Shift, Ctrl, or Alt keys are combined with the button is switched off after having been switched on, if the button to which is assigned “S”, “C”, or “A” is switched on, the predetermined operation can be done)

until before the button to which is assigned “S”, “C”, or “A” is switched off after having been switched on,

if the button that has been pre-designated to perform a predetermined operation when the Shift, Ctrl, or Alt keys are combined with the button is not turned on, and if a button other than a button which completes a combination that has been determined to perform another operation is turned on, as one writes the letters of the button to which is allocated “S”, “C”, or “A” that is appropriate to the current letter mode, the button that has been subsequently switched on could determine the operation conducted in combination situation with those other buttons before it is switched off.

Also, as the process of “c”

If an operation that cancels the recently completed operation when the Home button switches on until before the Esc button switches off after having been switched on is allocated to the Esc button in addition to its original function, the operation to cancel the recently completed operation when the Home button switches on until before the Esc button is switched off after having been switched on is carried out,

until before the Esc button is switched off after having been switched on, if the Home button does not switch on and a button other than a button which completes a combination that has been determined to perform another operation is turned on, the existing operation which is the Esc operation is performed. Then, the button that subsequently switches on can determine the operation performed by that button based on the combination situation with other buttons prior to that button being switched off.

By doing this, excepting the Ctrl, Shift, or Alt key which does not operate when switched on but including the function buttons or letter buttons which operate when turned on, one can also make it carry out another function in the context of a combination with other buttons that are switched on subsequently until it is switched off after having been switched on.

Here, if one were to explain the situation linked with “a communication terminal such as a cell phone, PDA, telephone, etc.,” (According to the given context, one can move out of the scope of the communication terminal and apply the present invention's method)

A cell phone ordinarily has a total of approximately 25 buttons, and these include 13 function buttons located on the front or side section of the device and 12 buttons composed of 3 columns/4 rows (Ten letter buttons to which are assigned 0˜9 numbers and characters and symbols, 1 button to which is allocated “*”, and 1 button to which is allocated “#”)

In existing methods, even if the function buttons are buttons that are located in the same area

their functions could differ according to what the present mode is (E.g., In the home screen, the right direction button allows one to move directly to the telephone directory menu but has the function of moving the cursor on the menu screen or when writing a letter)

If there are no operations relating to the present mode, no operation appears even if a button is hit (E.g., In the initial state, the internet link button performs an operation of connecting to the net and has the function of selecting a song in an MP3 mode but does not respond at all if hit in the letter writing mode) or

sometimes implements the same function no matter what and irrespective of the present mode (E.g., The end button takes the user to the home screen regardless of the current mode or takes one to the home screen after showing a message that asks whether the user permits the transfer and receiving the user's consent.)

And, as in a computer, the letter button always displays the letters as soon as it is switched on, but it does not carry out an operation other than displaying the letter when another button is turned on until before a certain letter button is switched off after having been switched on.

And, in the case of several letter being assigned to a single button

For the first letter, one can quickly hit the relevant button to display the letter but,

normally for the second and third letters, the user needs to hit several times such as double click or triple click (In terms of hitting the key several times, the letter is not determined not just by hitting the key several times but one must hit another button or hit the button that conveys the intent to select the already displayed letter (E.g., direction button) or wait for 2 seconds after which time the letter is automatically selected and the cursor moved) or apply a long press or others to display the letter.

Moreover, as a method that is proposed in a similar fashion as the present invention, if the button to which letters are allocated is switched on after switching on and off the button to which is assigned “*” or while it is turned on, then the second letter allocated to that button will be displayed. If the button to which letters are allocated is switched on after switching on and off the button to which is assigned “#” or while it is turned on, then the third letter allocated to that button will be displayed. Such a method has been proposed but there are several problems.

First, only in the case where letters are not allocated to “*” or “#”, the creation of a combination-inducing-button which allows the “*” or “#” to write a letter of a particular sequence that are allocated to other buttons is possible. (To provide an explanation for this, since when functioning as a combination-inducing-button that allows the writing of the second letter assigned to another button all the while a letter or letters are assigned to “*” button, there is no combination-inducing-button which allows for the writing of the second letter allocated to “*” button.)

Also, in respect to the hitting of the button to which is assigned “7” while pressing the button to which is allocated “*” and the hitting of the button to which is assigned “9” while pressing the button to which is allocated “#”, it is very difficult to write letters with both thumbs getting in each other's way since the buttons of each pair of the button to which is assigned “*”, and the button to which is assigned “7”, and the button to which is allocated the “#”, and the button to which is allocated “9” are placed vertically and in a continuous fashion.

Especially, the hitting of the button to which “7” is allocated with the right thumb while pressing the button to which “*” is assigned with the left thumb and hitting the button to which is allocated “9” with the left thumb while pressing the button to which is allocated “#” with the right thumb intensify the problem of both thumbs getting in each other's way.

Moreover, when exploring the scope of movement of the thumb, this is dramatically reduced when the present invention's method is applied.

(The reason that the scope of the movement of the fingers is mentioned here is because until now, I experienced much inconvenience when trying to use the function buttons such as the arrow button or cancel button located only slightly out of the letter buttons part while typing letters and because according to the explanation given in the following 30 pages or so about the present invention, the scope of movement of the finger can be significantly reduced when compared to existing methods vis-a-vis only within the letter buttons part.

It is because if the method of this invention is applied, the function of the function buttons that are frequently used while typing letters, such as the arrow button or cancel button, is additionally allocated to the letter buttons part, and because even though the special letters have been additionally assigned, one can operate the functions of a function button or type special characters in the letter buttons part within 2 hits and without having to change the letter mode.)

The reason for this is that if only the buttons in columns 1 and 3 are designated as combination-inducing-buttons in the method derived from the present invention, the left thumb only needs to be responsible for columns 1 and 2 (or just 1) and the right thumb for column 3 (or columns 2 and 3) while typing. However, if * or # is designated as a combination-inducing-button, the left and right thumb both need to be responsible for all of columns 1, 2, and 3 while typing.

Also, based on the present invention's method, if the combination-inducing-button is selected only from among the buttons found in rows 1˜3 and there is only the letter button 0 in row 4, then the thumb for the most part moves from row 1 to row 3. However, if * or # is selected as a combination-inducing-button, both thumbs will always move across rows 1, 2, 3, and 4 when trying to type.

Furthermore, as shall be explained later, since with the * or #, it is possible to designate only those combination-inducing-buttons that allow for the writing of letters of two kinds of sequential number, it is possible to designate combination-inducing-buttons that allow for the typing of the first and second letters completely and of the second and third letters incompletely, and because of this, the user can type 20 letters completely and 30 letters incompletely within two hits. However, based on the present invention's method, since it is possible to designate the 0˜9 buttons to which are allocated letters as commination inducing buttons, one can type more letters within 2 hits. From a psychological point of view, when compared to 2 hits, one experiences much greater inconvenience with 3 hits or more or a long press.

(The term “incomplete” as employed above refers to the inability to resolve inconvenience arising when one does not designate a combination-inducing-button that allows the typing of the first letter when using a multi tab mode or the multi tab mode in conjunction with the combination button as shown below. To give an example of typing in English and Korean

1. English: When a chain of alphabets is allocated to the same letter button, the user waits for 2 seconds as a way of verification or moves the cursor by using the right arrow sign. This applies even for the first letter. If this is not observed, one will end up typing “b” instead of the intended “aa”.

2. Korean: When the front word has a supporting letter and if the final consonant (=supporting letter) of the front word and the first consonant of the latter word are allocated to the same button, one is to wait 2 seconds as a way of verifying the final consonant of the front word or move the cursor by hitting the right arrow sign. If this is not done, one ends up typing “□□(gakag)” instead of the intended “□□(gaggak)”.

In fact, it can be viewed that this kind of a phenomenon associated with the Korean mode is included in the case of the chain of alphabets referred to above in no. 1.)

Further, while the development process is completed for an ‘the method of entering with adjacent keys’, which sets those buttons that are located immediately to the left as combination-inducing-buttons, to the right, above, and below of the button to which the letter that is intended to be typed is allocated, and though this has some positive features, it can be said that one finds more frequently the fingers on both hands getting in each other's way because the instances where the letter button and another letter button are found in a linked fashion from top to bottom when the letter button to which the letter that is to be typed is allocated is combined with another letter button which has been turned into a combination-inducing-button that includes the immediately adjacent “*” and “#” are more frequent than when designating only “*” and “#” as combination-inducing-buttons.

Also, pressing the adjacent keys with both thumbs creates the problem of a large portion of the keyboard being covered over, and when trying to use the letter buttons, both thumbs have to be responsible for all of rows 1, 2, and 3.

And, in terms of the method of entering with adjacent keys, the selection of a combination-inducing-button is determined by the sequential position at which the desired letter is placed in respect to the button to which the letter that is to be typed is allocated, and as such, it is easy for the user to become confused when trying to figure out which button to utilize as a combination-inducing-button when typing in a letter.

For example, let us look a situation where 3 letters are allocated to a single button,

The reason that the button to which is assigned the desired letter is set as a single hit is to type in the letter that is allocated as number 2 (=center), and

when it is designated that the button that is to the left of the button to which the sought after letter is allocated becomes the combination-inducing-button for typing the first letter that is assigned to the button to which is allocated the desired letter, and

the button that is to the right of the button to which the desired letter is allocated is designated to become the combination-inducing-button for typing the third letter assigned to the button to which the sought after letter is allocated. When this happens,

if ‘G, H, and I’ are assigned to button 4,

one needs to carry out a single hit of button 4 to type in ‘H’,

and to type in ‘I’, one does this by setting button 5 on the right as a combination-inducing-button and combining it with button 4.

To type in ‘G’, since making the button on the left a combination-inducing-button and then trying to enter by combining it with button 4 do not work due to the absence of a button on the left, and hence, there is no choice but to adopt the method of turning button 1 located in the upper part into a combination-inducing-button, which results in reduced consistency (That is why there arises the general rule that the left button or the upper button should be set as a combination-inducing-button which types the first letter.)

In effect, buttons 1, 4, and 7 in column 1 will see the same problem as above.

Also, since buttons 3, 6, and 9 in column 3 do not have right side buttons, there is no option but to adopt the method of using the lower buttons as a combination-inducing-button that allows the typing of the third letter, which results in decreased consistency. (That is why there arises the general rule that the right side button or the lower button is set as a combination-inducing-button that allows the inputting of the third letter.)

In effect, when typing the first letter allocated to a button in column 1 and the third letter allocated to a button column 3, it may be easy to become confused as to which button to apply as a combination-inducing-button unless one is proficient at it.

Especially in the case of button 1, which does not have either a left or upper button, meaning that there is no way of writing a left side letter (=first letter), it is possible to allocate only 2 letters to button 1.

Thus, when a given button operates as a combination-inducing-button, the user must select the combination-inducing-button by taking into consideration the relationship of spatial position between the button to which the sought after letter is assigned and the combination-inducing-button in accordance with the sequence of the letter in relation to the button to which the sought after letter is allocated. Moreover, when the same button operates as a combination-inducing-button, the combination inducing function alters, and the result is the problem of diminishing consistency.

For example, since button 2

is found to the right of button 1, it also functions as a combination-inducing-button that types the third letter allocated to button 1, but

because it is located to the left of button 3, it also functions as a combination-inducing-button that allows the typing in of the first letter assigned to button 3, and as such, there is a need for an extra effort to carefully find out the sequence of the letter of the button to which is allocated the sought after letter and then to select the combination-inducing-button accordingly.

Further, in the case of a sliding type cell phone,

it is difficult to hit button 1 with the right thumb while pressing button 4 with the left thumb because the right thumb is stuck at the upper part of the sliding phone,

and it is difficult to hit button 3 with the left thumb while pressing button 6 with the right thumb because the left thumb gets stuck at the upper part of the sliding phone.

Nonetheless, according to the present invention's method, the selection of the combination-inducing-button is not based on the relationship of spatial position with the button to which is allocated the sought after letter but like the existing method of confirming and solidifying the buttons * and # as combination-inducing-buttons that allows the typing of the first (or second) and third letters, one can designate

buttons 1 and 3 as combination-inducing-buttons that allow for typing the second (or first) letter,

buttons 4 and 6 as combination-inducing-buttons that allow the typing of the third (or second) letter,

buttons 7 and 9 as combination-inducing-buttons that allow the typing of fourth (or third) letter,

and buttons * and # as combination-inducing-buttons that allow the typing of fifth (or fourth) letter,

buttons 2 and 8 as combination-inducing-buttons that allow the typing in of sixth (or fifth) letter,

and buttons 5 and 0 as combination-inducing-buttons that allow the entering of seventh (or sixth) letter, and as a result, one can dramatically increase the number of letters assigned to each button (including special characters) while typing each of all letters in 2 hits or less, which results in the consistency of the function of the combination-inducing-buttons.

(Of course, if one were to take into account that no letter was assigned to buttons * and # above, the scope of movement of the finger increased, and fingers got in the way of each other, one can designate button # as a combination-inducing-button that allows the typing of the eighth (or seventh) letter since it is possible to set buttons * and # as combination-inducing-buttons that perform functions different from each other.

Also, since it may be that buttons * and #, could come before or after the letter button in terms of their function as combination-inducing-buttons, button * can be designated as a combination-inducing-button that comes after the letter button so that the ninth (or eighth) letter is typed in and button # can be designated as a combination-inducing-button that comes after the letter button so that the tenth (or ninth) letter is typed in.)

If one were to describe the above examples so that they could be utilized in terms of a more general situation that could support the content found in the claims,

even though a certain button has been designated as a combination-inducing-button that brings on a specific type of operation (E.g., an operation which types the second letter that is allocated to another button) when it is combined with another button, a method which makes possible an identical type of operation when the other button that induces the same type of operation as that specific type of operation and the another button mentioned 3 lines above are combined is suggested, that is, to propose a method where more than 1 case in which a manufacturer or non manufacturer designates more than 2 combination-inducing-buttons that bring on the same kind of operation. And there

it can be considered as a method of designation that the type of operation that induces when a certain button operates as a combination-inducing-button does not change depending on the relationship of spatial position with another button, and is consistent irrespective of the relationship of spatial position with another button.

From now, an explanation will be given with a specific example.

In terms of buttons that are similar to the letter buttons on ordinary telephone varieties to which is allocated 0˜9, *, #, and other letters (0˜9, *, and # shall be considered as representative letters),

until each of the letter buttons are switched off after having been switched on,

when another letter button is turned on,

one designates that two random buttons (button no. 1 and button no. 2) be included as combination-inducing-buttons which allow that a letter button that is switched on first types the first letter allocated to a letter button switched on later or a letter button that is switched on later types the first letter allocated to a letter button switched on first

Moreover, from among the buttons excluding the abovementioned from button no. 1 to button no. 2,

one designates that a random button no. 3 and button no. 4 be included as combination-inducing-buttons which allow a letter button that switches on first to type the second letter allocated to the letter button that switches on later or a letter button that switches on later to type the second letter allocated to the letter button that is turned on first, and

Also, from among the buttons excluding the abovementioned from button no. 1 to button no. 4,

one designates that a random button no. 5 and button no. 6 be included as combination-inducing-buttons which allow a letter button that switches on first to type the third letter allocated to the letter button that switches on later or a letter button that switches on later to type the third letter allocated to the letter button turned on first.

Moreover, from among the buttons excluding the abovementioned from button no. 1 to button no. 6,

one designates that a random button no. 7 and button no. 8 be included as combination-inducing-buttons which allow a letter button that switches on first to type the fourth letter allocated to the letter button that switches on later or a letter button that switches on later to type the fourth letter allocated to the letter button turned on first.

from among the buttons excluding the abovementioned from button no. 1 to button no. 8,

one designates that a random button no. 9 and button no. 10 be included as combination-inducing-buttons which allow a letter button that switches on first to type the fifth letter allocated to the letter button that switches on later or a letter button that switches on later to type the fifth letter allocated to the letter button turned on first, and

from among the buttons excluding the abovementioned from button no. 1 to button no. 10,

one designates that a random button no. 11 and button no. 12 be included as combination-inducing-buttons which allow a letter button that switches on first to type the sixth letter allocated to the letter button that switches on later or a letter button that switches on later to type the sixth letter allocated to the letter button turned on first.

For this purpose, including the method of the manufacturer or non manufacturer making the designation at their own discretion, one can adopt all methods that permit the existence of more than 1 case where the 2 or more combination-inducing-buttons that bring on the same operation are designated.

If we consider several tables that show as concrete example the above method,

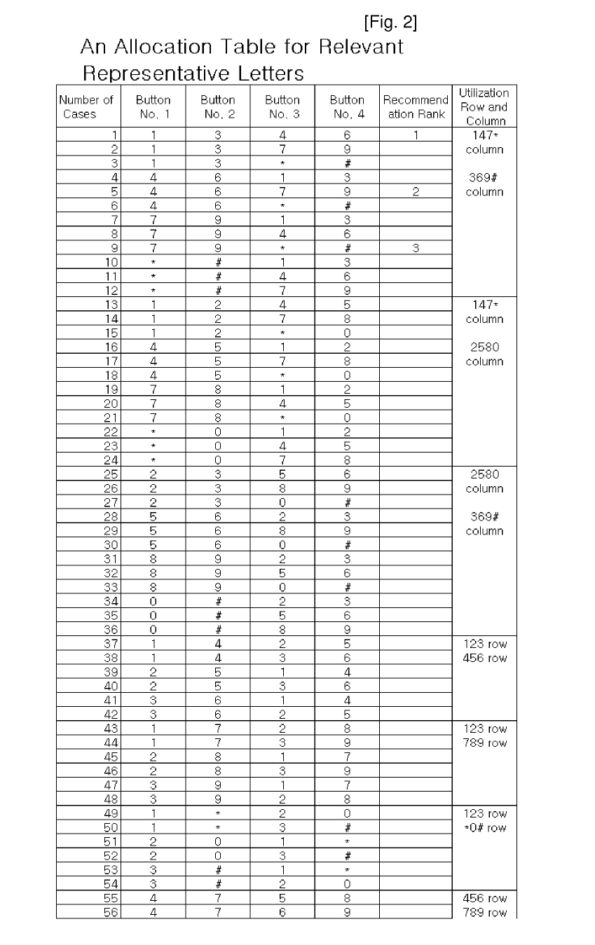

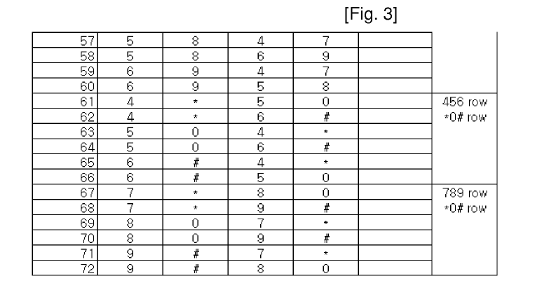

FIGS. 2 and 3 are several combination tables among the many combinations that could become any of the buttons 1 to 4, and

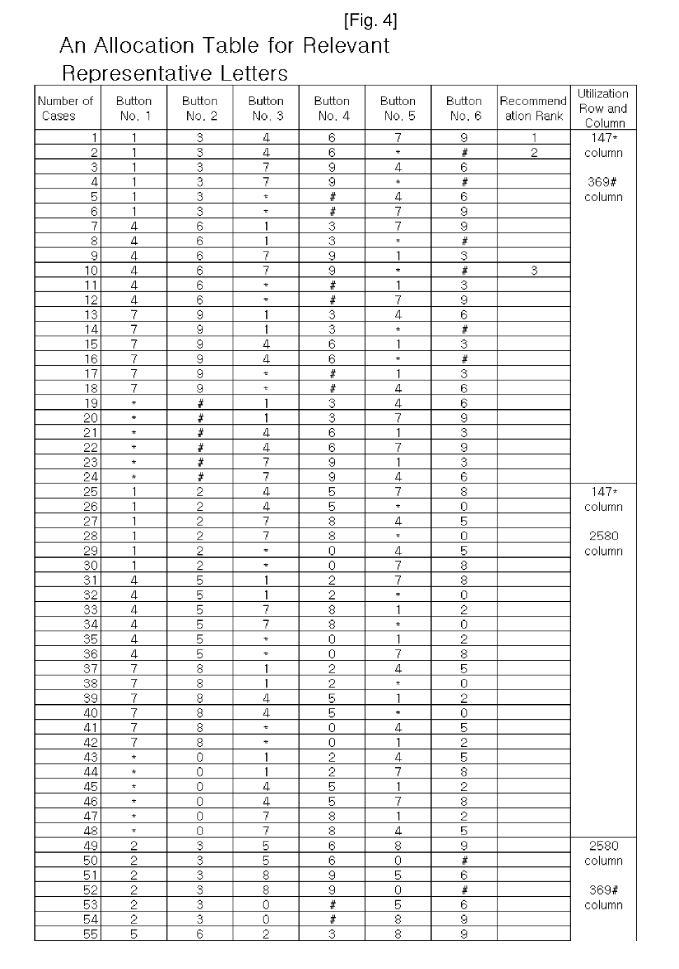

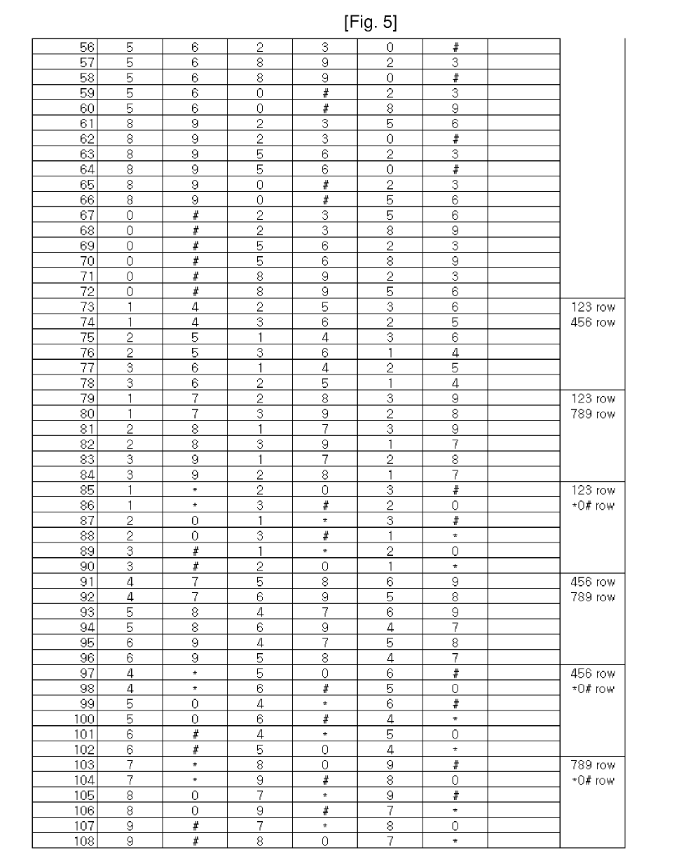

FIGS. 4 and 5 are several combination tables among the many combinations that could become any of the buttons 1 to 6, and

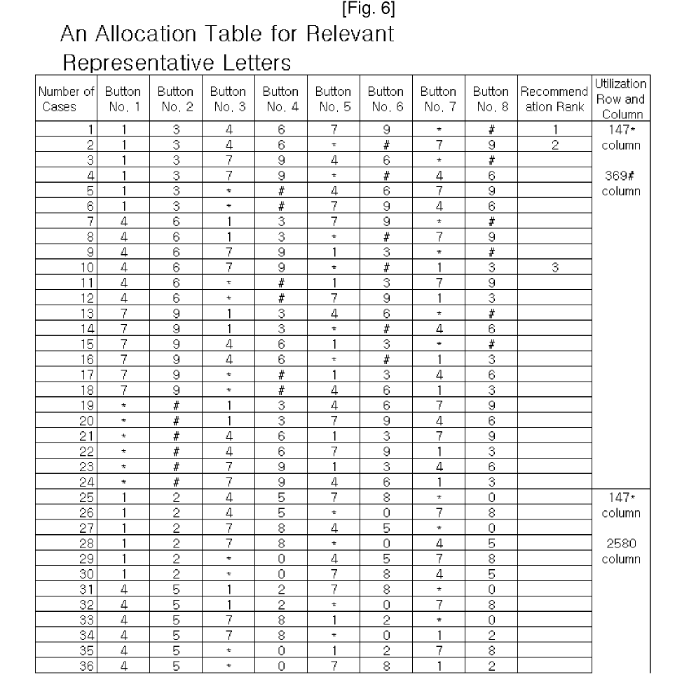

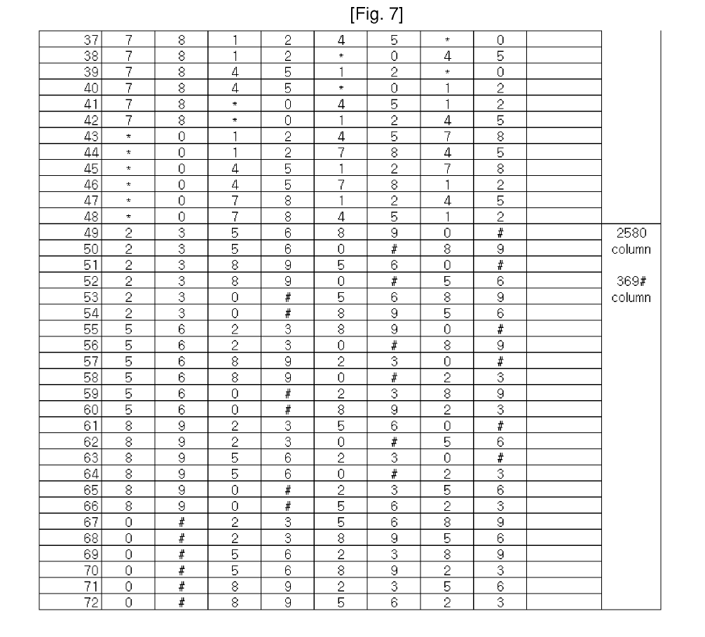

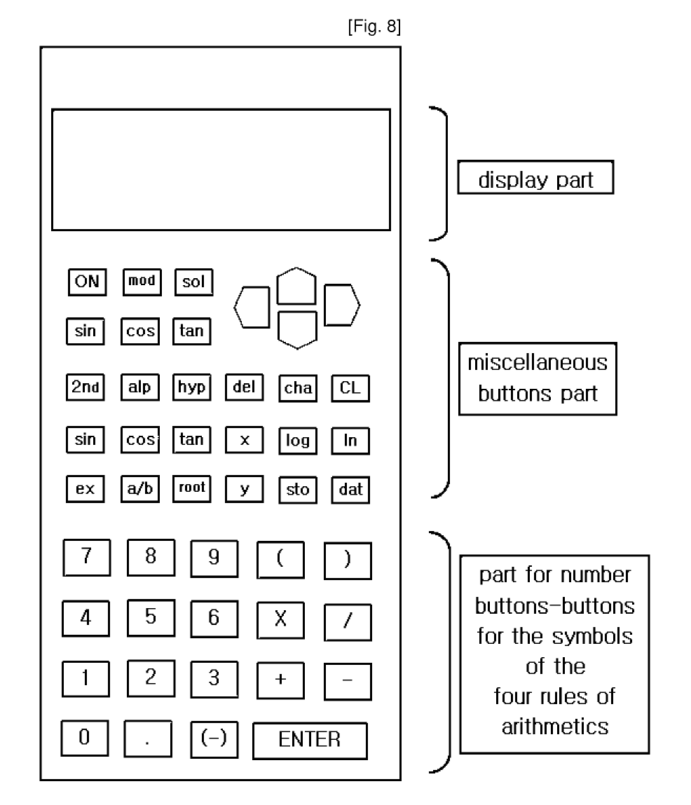

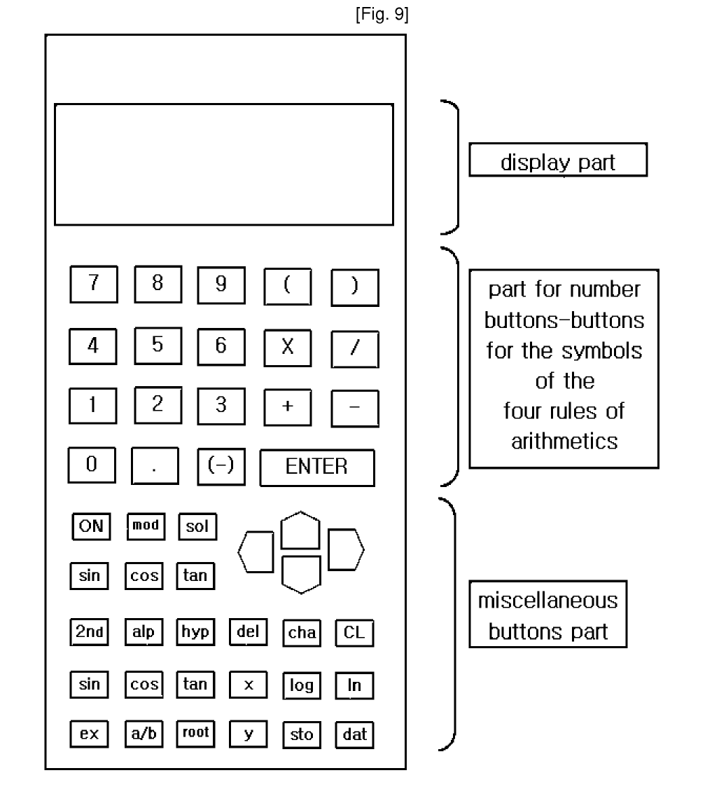

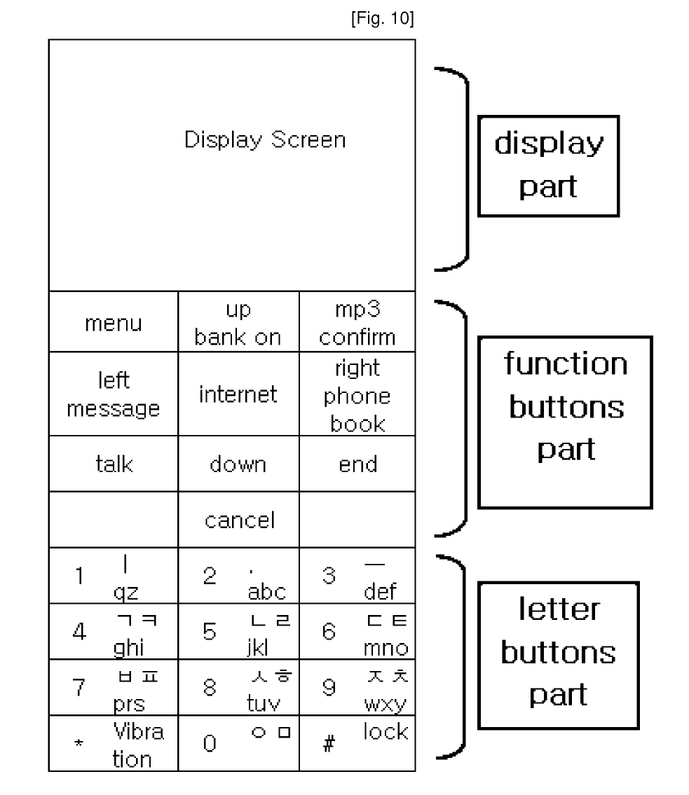

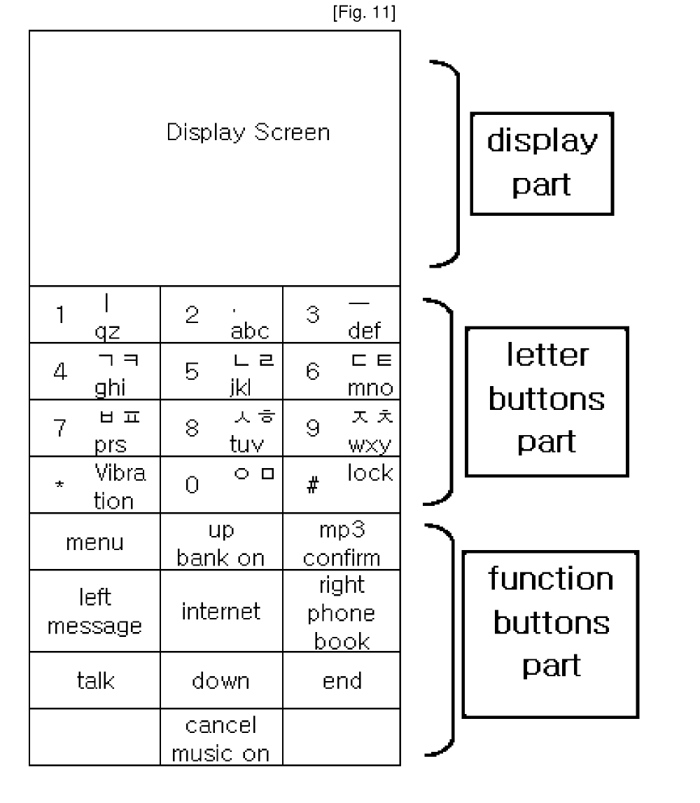

FIGS. 6 and 7 are several combination tables among the many combinations that could become any of the buttons 1 to 8, and

in reference to the button combinations that are more than the preceding number, if one is a professional in this area, he or she would understand how that combination would transpire even if tables are not furnished here.

(In the table in FIG. 2 or FIG. 7

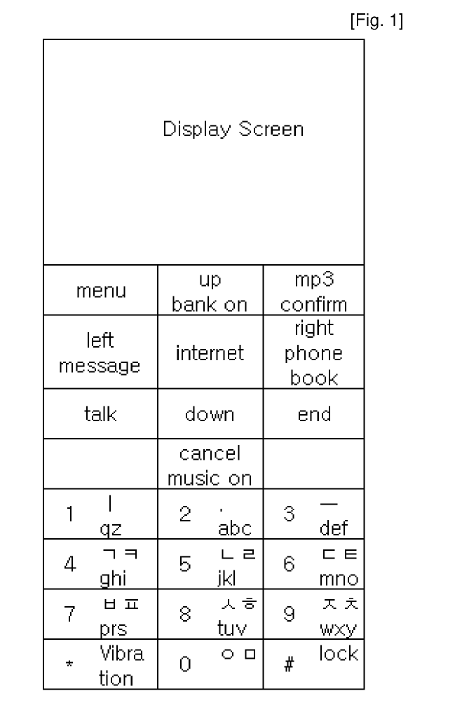

Among 0˜9, *, #, and other letters, 0˜9, *, and # are considered as representative letters, and it can be seen that the representative letters signify a position in the generally understood 4 column 3 row keyboard like ‘FIG. 1’ and not the letters themselves. Therefore, in respect to the allocation position of the buttons on the 4 column 3 row keyboard that looks like the 3 column 4 row board turned 90 degrees, it is appropriate to make the application by replacing the word “column” with “row” and the word “row” with “column” in the ‘utilization column/row’ of the table. Of course, even in such a case, the representative letters signify the position of the 4 columns 3 rows and not the letters themselves.)

As such, when the present invention's method is applied, since one can also set two or more combination-inducing-buttons that allow the typing of the letters of random sequence of the switched on button at the letter buttons, there is the advantage that while one can prevent the fingers from touching each other and getting in each other's way, reduce the scope of movement of the fingers, and assign the same number of letters to all the buttons, when the “*” button and “#” button are not set as combination-inducing-buttons that allow the typing in of letters, they can be used as buttons with other functions (including the existing separate functions carried out according to existing modes).

In the next example, this is treated in detail.

On the one hand, in reference to existing cell phones, a certain operation is being conducted immediately after the button is switched on. If the present invention's method is applied here, if a combination button to which a specific operation is designated switches on in advance until the button is switched off after having been turned on, one has the option of either performing the specific operation designated in advance or the original operation of the button

a. To look at a specific case, at existing method, the menu screen appears as soon as the menu button is switched on. However, if the method of this invention is applied, when the right side direction button is switched on until before the menu button is turned off after being switched on, the screen shifts to the reserve menu. In this way, even if due to the context of limited space and number of buttons one cannot see the reserve message that has a low frequency of use with the use of just one function key, the user can still change the screen to the one that displays the reserve message via combination of buttons. If until before the menu button is switched off after being turned on, the right direction button is not switched on and another button that is not combination completing button set for another operation is switched on, the menu screen is made to pop up. While this takes place,

the button that is switched on next determines the operation derived from that button as based on the combination situation linked with other buttons that is switched on before that button is switched off.

In this way, one can also set as a combination-inducing-button the button to which letters are allocated.

b. If the button to which is allocated “1” and the button to which is assigned 3 are designated in advance as combination-inducing-buttons that bring on the typing of the second letter of another letter button when another button is turned on, until before the button to which is assigned “1” or “3” is switched off after being switched on, with the “1” and “3” buttons being created in addition to the original “1” and “3” buttons with their respective functions, when until before the button to which is allocated “1” or the button to which is allocated “3” is switched off after being switched on another letter button is turned on, it will be made that the second letter of another letter button is typed. If until before the button to which “1” is assigned or the button to which “3” is assigned another letter button is not switched on and another button which is not the one that completes the combination that has another operation designated is switched on, the first letter of the button to which is allocated “1” or the button to which “3” is assigned that is appropriate to current letter mode,

which is the original operation. While this takes place, the button that is switched on next determines the operation derived from that button based on the combination situation linked with another button that is switched on before the that button is switched off.

c. If the button to which is allocated “1” is designated in advance to prompt a change to a screen that shows the reserve message when the menu button is switched on until before the button to which is allocated “1” is switched off after being switched on, besides the original function of allowing the entering of the letter allocated to that button, when the menu button is switched on until before the button to which is allocated “1” turns off after being switched on, it changes to the screen that shows the reserve message. If until before the button to which is assigned “1” is turned off after being switched on, the menu button is not switched on and another button that is not even a key which completes the combination to which another operation is designated switches on, then the first letter of the button to which is allocated “1” that is appropriate for the current mode is typed, which is the original operation. While this take place, the button that is switched on next determines the operation derived from that button based on the combination situation linked with other buttons that are switched on before that button is switched off.

d. Also, if the button to which is allocated “4” and the button to which “6” is assigned are designated in advance as combination-inducing-buttons that bring on the typing of the third letter of another letter button when another button is switched on after the button to which is allocated “4” or the button to which is allocated “6” is switched on, besides the original function of allowing the entering of the letter allocated to that button, when another button switches on before the button to which “4” is assigned or the button to which “6” is allocated switches off after being turned on, it is made that the third letter of another letter button is typed. And if until before the button to which “4” is allocated or the button to which “6” is allocated switches off after having been switched on another letter button is not switched on and another button which is not even a button that completes the combination for which is designated another operation is turned on, then the first letter of the button to which “4” is allocated or of the button to which “6” is assigned that is appropriate in the current letter mode gets typed, which is the original operation. While this takes place, the button that switches on next determines the operation derived from that button based on the combination situation linked with other buttons that have been switched on before that button turns off.

e. If the button to which is allocated “7” and the button to which is allocated “9” is designated in advance as a combination-inducing-buttons that bring on the operation resulting from a long press of another button when another button is switched on after the button to which is allocated “7” or the button to which is assigned “9” switches on, besides the original function of allowing the typing of the letter that has been allocated to that button (It is assumed that the number allocated to that button gets typed), when another button switches on until before the button to which “7” is assigned or the button to which “9” is allocated switches off after being turned on, it is made that the number assigned to another letter button is typed. And if until before the button to which “7” is allocated or the button to which “9” is allocated switches off after having been switched on, another letter button is not switched on and another button which is not even a button that completes the combination for which is designated another operation is turned on, then the first letter of the button to which “7” is allocated or of the button to which “9” is assigned that is appropriate in the current letter mode gets typed, which is the original operation. While this takes place, the button that switches on next determines the operation derived from that button based on the combination situation linked with other buttons that have been switched on before that button turns off.

f. If in the letter typing mode, it is designated in advance that each letter button carries out the operation of pressing the direction button according to the number that has been allocated to that letter, when the direction button is switched on until before each letter button turns off after being switched on, besides the function of typing letters, when the direction button switches on until before each letter button switches off after having been turned on, then one can perform the operation relating to the direction button being hit the same number of times as that which was allocated to that letter button. If until before each letter button turns off after being switched on, the direction button is not switched on and another button which is not even a button that completes the combination for which is designated another operation is switched on, then the first letter of the letter button appropriate to the current letter mode is typed, which is the original operation of that letter button. And while this takes place, the button that switches on next determines the operation derived from that button based the combination situation linked with other buttons that have been switched on before that button is turned off.

g. If in the letter typing mode, it is designated in advance that the letter button to which “7” is allocated prompts a change to a screen that shows right away a specific set of special characters that will be typed with the present cursor if the call button switches on until before the button to which is “7” is allocated turns off after being switched on, besides the function that allows for the typing of the letters allocated to that button,

it will be changed to the screen that displays a specific set of special characters when the call button switches on until before the button to which “7” is assigned turns off after being switched on. If until before the letter button to which “7” is allocated turns off after being switched on, the call button is not switched on and another button which is not even a button that completes the combination for which is designated another operation is switched on, then the first letter of the button to which “7” is allocated that is appropriate to the current letter mode is typed, which is the original operation of that letter button. And while this takes place, the button that switches on next determines the operation derived from that button based on the combination situation linked with other buttons that have been switched on before that button is turned off.

h. If in the letter typing mode, it is designated in advance that the letter button to which “7” is allocated prompts that specific special characters that will be typed with the present cursor are typed right away if the call button switches on until before the button to which is “7” is allocated switches off after being turned on, besides the function that allows for the typing of the letters allocated to that button, it will be that specific special characters will be typed if the call button switches on before the button to which “7” is assigned turns off after being switched on. If until before the letter button to which “7” is allocated turns off after being switched on, the call button is not switched on and another button which is not even a button that completes the combination for which is designated another operation is switched on, then the first letter of the button to which “7” is allocated that is appropriate to the current letter mode is typed, which is the original operation of that letter button. And while this takes place, the button that switches on next determines the operation derived from that button based on the combination situation linked with other buttons that have been switched on before that button is turned off.

i. Also, by allowing one to save an operation that has been designated in advance as a name or number, if in the letter typing mode, it is designated in advance that the letter button to which “7” is allocated carries out a predetermined operation when the user types in the operation name or number after a message appears that prompts one to type the predetermined operation name or number, when the confirmation button switches on until before the button to which is “7” is allocated switches off after having been switched on besides the function that allows for the typing of the letters allocated to that button, then one can perform the operation that has been designated in advance by entering that operation name or number when a message appears directing the user to type in the predetermined operation name or number if the confirmation button switches on before the letter button to which “7” is allocated switches off after having been turned on. If until before the letter button to which “7” is allocated turns off after being switched on, the confirmation button is not switched on and another button which is not even a button that completes the combination for which is designated another operation is switched on, then the first letter of the button to which “7” is allocated that is appropriate to the current letter mode is typed, which is the original operation of that letter button. And while this takes place, the button that switches on next determines the operation derived from that button based on the combination situation linked with other buttons that have been switched on before that button is turned off.

At this time, in terms of cell phones, if one were to provide an explanation by comparing existing methods with the methods applied in the present invention,

when a person wants to send the following text message on a cell phone: “I LOVE YOU FOR EVER a red heart symbol”

In an existing method of a mobile phone (Manufacturer: Samsung Electronics) as shown in FIG. 1

The user brings forward the send text message screen and selects the option for English capital letters mode, and then

1. Button 4: Displays G (Since it is not a confirmed state, only the cursor blinks)

2. Button 4: Displays H (Since it is not a confirmed state, only the cursor blinks)

3. Button 4: Displays I (Since it is not a confirmed state, only the cursor blinks)

4. The right direction button or wait for 2 seconds: The I gets selected

5. The right direction button: Moves one space

6. Button 5: Displays J (Since it is not a confirmed state, only the cursor blinks)

7. Button 5: Displays K (Since it is not a confirmed state, only the cursor blinks)

8. Button 5: Displays L (Since it is not a confirmed state, only the cursor blinks and confirmation is made when the next button switches on)

9. Button 6: Displays M (Since it is not a confirmed state, only the cursor blinks)

10. Button 6: Displays N (Since it is not a confirmed state, only the cursor blinks)

11. Button 6: Displays O (Since it is not a confirmed state, only the cursor blinks and confirmation is made when the next button switches on)

12. Button 8: Displays T (Since it is not a confirmed state, only the cursor blinks)

13. Button 8: Displays U (Since it is not a confirmed state, only the cursor blinks)

14. Button 8: Displays V (Since it is not a confirmed state, only the cursor blinks and confirmation is made when the next button switches on)

15. Button 3: Displays D (Since it is not a confirmed state, only the cursor blinks)

16. Button 3: Displays E (Since it is not a confirmed state, only the cursor blinks)

17. Right direction button or wait for 2 seconds: E gets selected

18. Right direction button: Move one space

19 Button 9: Displays W (Since it is not a confirmed state, only the cursor blinks)

20. Button 9: Displays X (Since it is not a confirmed state, only the cursor blinks)

21. Button 9: Displays Y (Since it is not a confirmed state, only the cursor blinks and confirmation is made when the next button switches on)

22. Button 6: Displays M (Since it is not a confirmed state, only the cursor blinks)

23. Button 6: Displays N (Since it is not a confirmed state, only the cursor blinks)

24. Button 6: Displays O (Since it is not a confirmed state, only the cursor blinks and confirmation is made when the next button switches on)

25. Button 8: Displays T (Since it is not a confirmed state, only the cursor blinks)

26. Button 8: Displays U (Since it is not a confirmed state, only the cursor blinks)

27. Right direction button or wait for 2 seconds: U gets selected

28. Right direction button: Moves one space

29. Button 3: Displays D (Since it is not a confirmed state, only the cursor blinks)

30. Button 3: Displays E (Since it is not a confirmed state, only the cursor blinks)

31. Button 3: Displays F (Since it is not a confirmed state, only the cursor blinks and confirmation is made when the next button switches on)

32. Button 6: Displays M (Since it is not a confirmed state, only the cursor blinks)

33. Button 6: Displays N (Since it is not a confirmed state, only the cursor blinks)

34. Button 6: displays O (Since it is not a confirmed state, only the cursor blinks and confirmation is made when the next button switches on)

35. Button 7: Displays P (Since it is not a confirmed state, only the cursor blinks)

36. Button 7: Displays R (Since it is not a confirmed state, only the cursor blinks)

37. Right direction button or wait for 2 seconds: R gets selected

38. Right direction button: Move one space

39. Button 3: Displays D (Since it is not a confirmed state, only the cursor blinks)

40. Button 3: Displays E (Since it is not a confirmed state, only the cursor blinks and confirmation is made when the next button switches on)

41. Button 8: Displays T (Since it is not a confirmed state, only the cursor blinks)

42. Button 8: Displays U (Since it is not a confirmed state, only the cursor blinks)

43. Button 8: Displays V (Since it is not a confirmed state, only the cursor blinks and confirmation is made when the next button switches on)

44. Button 3: Displays D (Since it is not a confirmed state, only the cursor blinks)

45. Button 3: Displays E (Since it is not a confirmed state, only the cursor blinks and confirmation is made when the next button switches on)

46. Button 7: Displays P (Since it is not a confirmed state, only the cursor blinks)

47. Button 7: Displays R (Since it is not a confirmed state, only the cursor blinks)

48. Right direction button or wait for 2 seconds: R get selected

49. right direction button: Moves one space

50. Button *: A mode change from English capital letters to special characters

51. Hit the down button 12 times: Moves to the group which has the red heart symbol

63. (=51+12) Button 5: Selection of the red heart symbol (This is a system where if one hits button 5 on the screen that displays the group which has the red heart symbol, then the red heart symbol is selected.)

Conversely, when one looks at an example showing the application of the present invention's method,

As an a priori condition

A.

When the button to which “1” is allocated and the button to which “3” is allocated are designated in advance as combination-inducing-buttons that allow the typing of the second letter of another letter button when another button switches on after the button to which “1” or “3” are allocated switches on, besides the original function that allows for the typing of the letter allocated to that button, the second letter of another letter button is typed when another button switches on until before the button to which is allocated “1” or “3” turns off after having been switched on.

And if until before the button to which “1” or “3” is allocated switches off after having been switched on, another letter button is not switched on and another button which is not even a button that completes the combination for which is designated another operation is turned on,

then the first letter of the button to which “1” or “3” is allocated that is appropriate in the current letter mode gets typed, which is the original operation. While this takes place, the button that switches on next determines the operation derived from that button based the combination situation linked with other buttons that have been switched on before that button is turned off.

If the button to which “4” is allocated and the button to which “6” is allocated are designated in advance as combination-inducing-buttons that allows for the typing of the third letter of another letter button when another button switches on after the button to which “4” or “6” are allocated switches on, besides the original function that allows for the typing of the letter allocated to that button,

the third letter of another letter button is typed when another button switches on until before the button to which is allocated “4” or “6” turns off after having been switched on. And if until before the button to which “4” or “6” is allocated switches off after having been switched on, another letter button is not switched on and another button which is not even a button that completes the combination for which is designated another operation is turned on,

then the first letter of the button to which “4” or “6” is allocated that is appropriate in the current letter mode gets typed, which is the original operation. While this takes place, the button that switches on next determines the operation derived from that button based on the combination situation linked with other buttons that have been switched on before that button is turned off.

B. In the send text message mode, when the button to which “1” is allocated is designated in advance as a combination-inducing-button that allows for the typing of a red heart symbol by the cursor when the menu key switches on until before the button to which “1” is allocated switches off after being switched on, besides the original function that allows one to type the letter allocated to that button, a red heart symbol is displayed by the current cursor when the menu key switches on until before the button to which is allocated “1” switches off after having been turned on. And if until before the button to which “1” is allocated switches off after having been switched on, the menu key is not switched on and another button which is not even a button that completes the combination for which is designated another operation is turned on,

then the first letter that is appropriate in the current letter mode gets typed, which is the original operation. While this takes place, the button that switches on next determines the operation derived from that button based on the combination situation linked with other buttons that have been switched on before that button is turned off.

C. In the send text message mode, when the button to which “1” is allocated is designated in advance as a combination-inducing-button that brings on the operation of displaying in the current cursor a special characters group to which belongs the red heart symbol when the cancel key switches on until before the button to which “1” is allocated switches off after being switched on, besides the original function that allows for the typing of the letter allocated to that button, in the current cursor, a special characters group to which belongs the red heart symbol is displayed when the cancel key switches on until before the button to which “1” is allocated switches off after being switched on. And if until before the button to which “1” is allocated switches off after having been switched on, the cancel key is not switched on and another button which is not even a button that completes the combination for which is designated another operation is turned on,

, then the first letter that is appropriate in the current mode gets typed. While this takes place, the button that switches on next determines the operation derived from that button based on the combination situation linked with other buttons that have been switched on before that button is turned off.

D. Whatever the mode, if a direction key switches on until before a button to which is assigned a number switches off after being switched on, then it is made that the direction button operates as many times as the number assigned to the button to which is allocated a number. And if until before the button to which a number is allocated switches off after being switched on, a direction key is not switched on and another button which is not even a button that completes the combination for which is designated another operation is turned on,

then the first letter that is appropriate in the current mode gets typed. While this takes place, the button that switches on next determines the operation derived from that button based on the combination situation linked with other buttons that have been switched on before that button is turned off.

Now based on the present invention's method, if one were to look at the process of typing “I LOVE YOU FOR EVER a red heart symbol” while taking into consideration the aforementioned priori conditions,

In the English capital letters mode

1. Button 6: Since the third letter of button 4 which will be switched on in sequence 2 is I, in order to set button 6 as a combination-inducing-button that selects the third letter allocated to the letter button which will be switched on next, one needs to maintain an “on” status until button 4 of sequence 2 is switched on. (Like button 6, button 4 also functions as a combination inducing button that selects the third letter of the letter button which will be switched on next, but since one cannot switch on button 4 of sequence 2 while maintaining an “on” status for button 4, one maintains an “on” status only for button 6).

2. Button 4: Selects I. (Since button 6 maintains an “on” status as it is)

3. Right direction button: Moves one space

4. Button 4: The third letter of button 5 that will be turned on in sequence 5 is L, and

The third letter of button 6 that will be switched on in sequence 6 is O, and

The third letter of button 8 that will be switched on in sequence 7 is V. As such,

by setting button 4 as a combination-inducing-button that selects the third letter allocated to the button that will be switched on next, one should maintain an “on” status for button 4 until button 5 of sequence 5, button 6 of sequence 6, and button 8 of sequence 7 is switched on.

Like button 4, button 6 can be set as a combination-inducing-button that selects the third letter allocated to the button that will be switched on next, and if button 6 is utilized as a combination-inducing-button in this situation, one cannot switch on button 6 of sequence 6 while maintaining an “on” status for button 6. As such, if one utilizes button 6 as a combination-inducing-button, “OV” can be typed only based on an increased number of procedures. Hence, this is not recommended in this situation.

5. Button 5: Selects L (Since the “on” status of button 4 is maintained as it is)

6. Button 6: Selects O (Since the “on” status of button 4 is maintained as it is)

7. Button 8: Selects V (Since the “on” status of button 4 is maintained as it is)

8. Button 1: Since the second letter of button 3 which will be switched on in sequence 9 is E, in order to set button 1 as a combination-inducing-button that selects the second letter allocated to the letter button which will be switched on next, one needs to maintain an “on” status until button 3 of sequence 9 is switched on. (Like button 1, button 3 also functions as a combination inducing button that selects the second letter of the letter button which will be switched on next, but since one cannot switch on button 3 of sequence 9 while maintaining an “on” status for button 3, one maintains an “on” status only for button 1)

9. Button 3: Selects E (Since the “on” status of button 1 remains as it is)

10. Right direction button: Moves one space

11. Button 4: The third letter of button 9 that will be switched on in sequence 12 is Y and

the third letter of button 6 that will be switched on in sequence 13 is O, and as such

by setting button 4 as a combination-inducing-button that selects the third letter allocated to the button that will be switched on next, one should maintain an “on” status for button 4 until button 9 of sequence 12 and button 6 of sequence 13 is switched on.

Like button 4, button 6 can be set as a combination-inducing-button that selects the third letter allocated to the button that will be switched on next, and if button 6 is utilized as a combination-inducing-button in this situation, one cannot switch on button 6 of the sequence 13 while maintaining an “on” status for button 6. As such, if one utilizes button 6 as a combination-inducing-button, “O” can be typed only based on an increased number of procedures. Hence, this is not recommended in this situation.

12. Button 9: Selects Y (Since the “on” status of button 4 remains as it is)

13. Button 6: Selects 0 (Since the “on” status of button 4 remains as it is)

14. Button 1 or Button 3: Since the second letter of button 8 which will be turned on in sequence 15 is U, in order to set button 1 or 3 as a combination-inducing-button that selects the second letter allocated to the button that will be switched on next, one should maintain an “on” status until button 8 of sequence 15 is switched on. Since the function of button 1 and button 3 is identical, button 1 or 3 is turned on.

15. Button 8: Selects U

16. Right direction button: Moves one space.

17. Button 4: The third letter of button 3 that will be switched on in sequence 18 will be F

Since the third letter of button 6 that will be switched on in sequence 19 will be O,

by setting button 4 as a combination-inducing-button that selects the third letter allocated to the button that will be turned on next, one should maintain an “on” status for button 4 until button 3 of sequence 18 and button 6 of sequence 19 are switched on.

Like button 4, button 6 can be set as a combination-inducing-button that selects the third letter allocated to the button that will be switched on next, and if button 6 is utilized as a combination-inducing-button in this situation, one cannot switch on button 6 of sequence 19 while maintaining an “on” status for button 6. As such, if one utilizes button 6 as a combination-inducing-button, “O” can be typed only based on an increased number of procedures. Hence, this is not recommended in this situation.

18. Button 3: Selects F (Since the “on” status of button 4 remains as it is)

19. Button 6: Selects O (Since the “on” status of button 4 remains as it is)

20. Button 3: Since the second letter of button 7 which will be switched on in sequence 21 is R, in order to set button 3 as a combination-inducing-button that selects the second letter allocated to the letter button which will be switched on next, one needs to maintain an “on” status for button 3 until button 7 of sequence 21 is switched on.

Like button 3, button 1 can be set as a combination-inducing-button that selects the second letter allocated to the button that will be switched on next, and if button 1 is utilized as a combination-inducing-button in this situation, in reference to switching on button 7 of sequence 21 while maintaining an “on” status for button 1, when one presses button 1, there arises the problem of not being able to see button 7 very well.

21. Button 7: Selects R (Since the “on” status of button 3 remains as it is)

22. Right direction button: Moves one space

23. Button 1: Since the second letter of button 3 which will be switched on in sequence 24 is E, in order to set button 1 as a combination-inducing-button that selects the second letter allocated to the letter button which will be switched on next, one needs to maintain an “on” status of button 1 until button 3 of sequence 24 is switched on. (Like button 1, button 3 also functions as a combination inducing button that selects the second letter of the letter button which will be switched on next, but since one cannot switch on button 3 while maintaining an “on” status for button 3 of sequence 24, one needs to maintain an “on” status only for button 1).

24. Button 3: Selects E (Since the “on” status of button 1 is maintained as it is)

25. Button 4 or Button 6: Since the third letter of button 8 which will be turned on in sequence 26 is V, in order to set button 4 or 6 as a combination-inducing-button that selects the third letter allocated to the button that will be switched on next, one should maintain an “on” status until button 8 of sequence 26 is switched on. Since the function of button 4 and button 6 is identical, button 4 or 6 is turned on.

26. Button 8: Selects V. (Since an “on” status of button 4 or 6 is maintained as it is)

27. Button 1: Since the second letter of button 3 which will be switched on in sequence 28 is E, in order to set button 1 as a combination-inducing-button that selects the second letter allocated to the letter button which will be switched on next, one needs to maintain an “on” status until button 3 of sequence 28 is switched on (Like button 1, button 3 also functions as a combination inducing button that selects the second letter of the letter button which will be switched on next, but since one cannot switch on button 3 while maintaining an “on” status for button 3 of sequence 28, one needs to maintain an “on” status only for button 1).

28. Button 3: Selects E (Since an “on” status for button 1 is maintained)

29. Button 3: Since the second letter of button 7 which will be switched on in sequence 30 is R, in order to set button 3 as a combination-inducing-button that selects the second letter allocated to the letter button which will be switched on next, one needs to maintain an “on” status of button 3 until button 7 of sequence 30 is switched on.

Like button 3, button 1 can be set as a combination-inducing-button that selects the second letter allocated to the button that will be switched on next, and if button 1 is utilized as a combination-inducing-button in this situation, in reference to switching on button 7 of sequence 30 while maintaining an “on” status for button 1, when one presses button 1, there arises the problem of not being able to see button 7 very well.

30. Button 7: Selects R (Since an “on” status of button 1 or button 3 is maintained as it is)

31. Right direction button: Moves one space

32. Button 1: In order to set button 1 as a combination-inducing-button that brings on the display of a red heart symbol on the current cursor when the menu button is switched on before the button to which button 1 is allocated is switched off after having been switched on, one maintains an “on” status until the menu key of sequence 33 is switched on. This is a method that applies the aforementioned priori condition “B”

33. Menu button: Displays a red heart symbol (Since an “on” status of button 1 is maintained as it is)

The above sequence 33 operation can be carried out based on the following two methods.

If we first look at the method applying the aforementioned priori condition, “C”,

a. The cancel button is switched on while button 1 is turned on: Displays the special characters group to which the red heart symbol belongs

b. Button 5: Selects the red heart symbol (Since the red heart is displayed as a fifth item)

Also, if we look at the method applying the aforementioned priori condition, “D”,

a. Button *: A mode shift from English capital letters mode to special characters mode

b. The down button is switched on while button 9 is turned on: Has the same effect as hitting the down button 9 times

c. The down button is switched on while button 3 is turned on: Has the same effect as hitting the down button 3 times (In effect, since this is the same as hitting the down button 12 times, it displays the special characters group to which belongs the red heart symbol).

d. Button 5: Selects the red heart symbol (Since the red heart is displayed as a fifth item)

To summarize the results of the example, in terms of typing just the words, “I LOVE YOU FOR EVER”, the existing method requires 48 instances of hitting the buttons on the keyboard while according to the method of this invention, only 30 are necessary, and at the same time, the latter method distributes workload more evenly between the two hands. Moreover, since the combination with the combination-inducing-button entails hitting the keys twice with both hands, it is much closer to the length of time associated with a short press like a single hit rather than to the length of time required for hitting the key twice like a double click (Theoretically, the time required to hit a key 100 times with one hand is same as hitting a key 100 times each by both hands for a total of 200 times. So, the method of hitting the key via a combination of both hands can be understood as more of a single hit or a one beat rather than 2 hits), one can complete the task of typing not simply within the time frame of 30/48 but much shorter than that.

Though we have given an example of the English alphabet in the preceding paragraphs, one can see a much more powerful effect when the method is applied to the Japanese language. Though, when applied to the English alphabet there are several positive features including the effectiveness suggested in the several words below, and though the biggest advantage is to make typing which can be done only with 3 or more hits possible with just 2 hits,

the Japanese letters number 50 and five letters are allocated to one button, and even for a letter that was typed after 4 or 5 clicks of the button, if the present invention's method is applied, the input can be made with just two hits. As such, it is expected that the work time will be reduced by 20˜30%,

and not 62.5% (30/48) as was the case for the English alphabet.

A similar advantage as the Japanese language would accrue to the Hindi language which is made up of 46 letters,

and a much bigger effect than for Japanese can be observed in the case of the That language, which is made up of 76 letters.

In any case, what this means is that the higher the number of letters in a given writing system, the greater the effect will be.

And, in reference to entering words that have a chain of alphabets allocated to the same button, since the need to move the cursor by hitting the right arrow key or to wait for 2 seconds as a way of verifying the alphabets that are written first can be eliminated, it can be said that that efficiency is raised significantly.

For example

“DEF” and “AC” in the word, “DEFACE” and

“TU” in the word, “TUVALU” and

“SPR” in the word, “SPRING” and

“CABBA” in the word, “CABBAGE” and

“BACC” in the word, “BACCY” and

“BAB” and “OON” in the word, “BABOON” and

“NOON” in the word, “AFTERNOON”

are a chain of alphabets allocated to the same button and even though this is so, the need to make a verification as in the existing multi tab method becomes unnecessary. (The Relevant Reasons are Given Above.)

For this reason, it is anticipated that the speed will be nearly the same as that observed in entering letters on a recently made cell phone that has as many buttons as that of a computer keyboard, which is developed for the purpose of increasing typing speed.

Also, as for the touchscreen mode, there are brands which when the keyboard appears on the screen, it covers most of the screen, but the method of this invention has the letters allocated to the buttons. Hence, such an occurrence obviously does not take place.

Likewise, in terms of typing the red heart symbol, the existing method necessitates the hitting of the button 14 times, but in light of the present invention's method, one needs to hit the button only twice at its minimum among others. What this means more broadly is that in respect to the act of typing special characters, in accordance with how the combination is designated, one can complete the operation enlarging the rate of significantly reducing time consumption much more so than when typing letters.

In stead of “*”, “#”, or other function buttons, if one were to set letter buttons as a combination-inducing-button, the scope of movement of the finger can be reduced. Also, if the right direction button function, the cancel button (Pronunciation unit or phoneme unit cancellation) function, etc., which are frequently used when typing letters, are placed in the letter buttons, one will likewise decrease the scope of movement of fingers.

If one were to summarize the strengths of the present invention when it is compared with only the multi tab method, it is as follows.

First, all letters (Approximately 100 or less) can be typed within two hits,

Second, when consecutively typing the letters allocated to the same button, the need to move the cursor by hitting the right arrow key or to wait for 2 seconds as a way of verifying the letter that are written first can be eliminated. Also, because of this, the scope of movement of the fingers can be reduced, and

third, there are cases where only one hit is necessary to type the letter assigned to the same sequence number (even if it is after sequence 2) allocated to another button (E.g., The 5th, 6th, and 7th process in the example of applying this invention in “I LOVE FOR EVER”)

And fourth, there are strengths explained by devoting approximately 20 pages in the introduction to the “Communication Terminal such as a Cell Phone, PDA, Telephone, etc.” delineated earlier.

To elaborate here,

For example, if one simply designates in advance a combination that carries out a specific operation only with the combination between letter buttons, English capital and small letters can be typed without changing the mode. Also, the phoneme allocation change for consonant or vowel buttons in Korean can be easily performed, and the same will be true for the phoneme allocation change to the method that allows for a convenient typing by the user of the letter allocated to a button in foreign language buttons.

Also, if existing methods such as the long press, double click, triple click, etc. are included here and harmonized, then indeed, a huge number of operations will be possible without having to go through the menu screen.

And, by applying the present invention's method to the letter writing modes such as “T9 and others”, if one were to confirm all or a part of the spelling and enter them accordingly, the user can rapidly type the words due to the decrease in the number of candidate words suggested by the device.

When searching data that is made up of letters indigenous to Japan or of Chinese characters with the search words composed of letters indigenous to Japan, which are not phonemes of phonetic symbol that include Hiragana or Gatagana of the Japanese language, the present invention's method dealt with below should be applied by thinking in terms of substituting the word ‘spelling’ or ‘alphabet’ used below with an indigenous letter.

Even if it is not for Japanese, the same kind of thinking remains valid when using an indigenous letter that is not a phoneme of a phonetic symbol or when utilizing letters such as special characters.

In reality, this was not separately mentioned because one could intuitively know that in the same manner, application is possible in the previous explanation, and it will be referred to because it may not be possible to be understood intuitively in the explanation that follows.

For example, in the case of the “T9 and others” method, when the user seeks to type ‘HOOD’, until now if the ‘4663’ button is pressed, since ‘GHI’ is allocated to ‘4’, ‘MNO’ to ‘6’, and ‘DEF’ to ‘3’, the device searches the dictionary database for their combination and when the device proposes ‘GONE’, ‘HOME’, ‘HOOD’, ‘HOOF’, ‘HONE’, AND ‘GOOF’ in accordance with frequency of use, the user must move the cursor over to ‘HOOD’ and make the selection. However, if one were to verify the ‘D’ of ‘HOOD’ and make the input by applying the present invention's method, the device suggests only 1 word, ‘HOOD’, which means that the user does not need to move the cursor but has simply to make the selection. This is because when one uses existing methods such as the “T9 and others”, one comes to realize that it becomes more convenient if a verification of the spelling of what specific sequence is made. For example, the more one confirms an alphabet that has a low utilization frequency, the greater the reduction there is in terms of the number of candidates.

To give an example of a method that verifies the spelling based on the present invention's method, when by designating ‘button 1’ or ‘button 3’ as a combination-inducing-button that types the first letter allocated to the button that switches on next, by designating ‘button 4’ or ‘button 6’ as a combination-inducing-button that types the second letter allocated to the button that switches on next, and by designating ‘button 7’ or ‘button 9’ as a combination-inducing-button that types the third letter assigned to the button that turns on next, one does not want to confirm the above spelling as ‘D’, it is only necessary to hit ‘button 3’ by itself. And if one wants to confirm the spelling as ‘D’, one needs to hit ‘button 3’ while pressing ‘button 1’.

And, since it is possible to reduce candidate words significantly by verifying a part of the spelling, though one were to type in only a part of a word without typing the candidate word (A state where the spelling is not confirmed, that is several words that are allocated to the pressed button), or confirmed word (A state where the spelling is verified), or unknown word (A state where the spelling cannot be predicted at all; on the computer, “*” or “?” are used to search for a word) that number as many as the spelling needed to complete a word, the number of candidate words which the device needs to display will not become too many. And it will be convenient because the user needs to make only a partial entry.

Further, since many special characters such as ‘*’, “#”, ‘, (comma)’, and ‘%’ are applied to the method of improvement for typing of characters including English and Chinese, etc., which is explained below in approximately 20 pages, it is advisable to ensure that special characters can be entered directly without a letter mode change by allocating such special characters and not just characters to the letter buttons.

And it is more advisable to allocate other special characters that are used frequently in writing a text message.

In modes including the “T9 and others” ordinarily, whenever an letter is entered, a word of the highest frequency that corresponds to the number of letters typed until the present time is consecutively displayed, and as such, in order to display the candidate words that include the desired word by just entering a partial spelling (candidate letters, confirmed letters, or unknown letters) of a word, a signal must be given which indicates that the user entered only a partial spelling.

(The reason for giving a signal indicating that only a partial spelling has been entered is because a logic has been utilized which makes the device automatically regard that the number of spelling that is the same number as the spelling which the user wanted has been entered if there is no signal. And if in the absence of a signal, the device automatically regards that the number of spelling that is less than the number of the spelling which the user wanted has been entered and accordingly, if the device automatically considers that all words or phrases (=a continuation of words) that include the entered spelling are to be displayed as a candidate word or phrase, then one must instead give the signal that the number of spelling is the same in order to reduce the number of candidates.

Also, a signal can be given in reference to the shortage or equality in the number of spelling.

It is requested here that the reader interpret in the same way hereafter that the manufacturer or the user can decide at his or her own discretion the method of giving the signal that indicates whether or not the number of spelling is smaller or the same.)

In such modes as the “T9 and others” above, ordinarily, whenever a letter is entered, the word with the highest frequency that corresponds to the number of letters entered until the present is displayed consecutively. To take this statement as an example,

If the user hits button 4 in order to type the word ‘HOOD’, then among “G, H, and I” allocated to button 4, “G” which has the highest frequency to the first letter is displayed first,

if the user next hits button 6, then “10” that has the highest frequency among the combination between button 4 (G, H, and I) that was pressed first and button 6 (M, N, and O) is displayed first, if the user then hits button 6, then “HON” which has the highest frequency among the combination of button 4 (G, H, and I), button 6 (M, N, and O), and button 6 (M, N, and O) is displayed first, if the user next hits button 3, then “GONE” that has the highest frequency among the combination of button 4 (G, H, and I), button 6 (M, N, and O), button 6 (M, N, and O), and button 3 (D, E, and F) is displayed first. However, one makes the selection by moving the cursor over to “HOOD” that comes after “HOME” and “HOOF”, which is displayed in a subsequent sequence depending on the frequency of use (The frequented or the displayed letter is expressed at the author's discretion).

In the above, instead of entering candidate letter (A state in which the spelling is not confirmed, that is several letters allocated to the pressed button), confirmed letter (A state in which the spelling is confirmed), or unknown letter (A state in which the spelling cannot be predicted at all; on the computer, “*” or “?” is often used to search for a word) in accordance with the same number of spelling which are necessary to complete the word, one types in only a part of the word, and the device still generates a display. To give an example of this,

When the user wants to type the word, “HOMEPORT”, in existing methods such as the “T9 and others”, all of button 4 (G, H, I), button 6 (M, N, O), button 6 (M, N, O), button 3 (D, E, F), button 7 (P, R, S), button 6 (M, N, O), button 7 (P, R, S), and button 8 (T, U, V) must be hit in order for the candidate word group that includes the candidate word “HOMEPORT” to be displayed, but if the present invention's method is applied, the user hits the combination-inducing-button+button 4 (“H” is confirmed), button 6 (M, N, O), the combination-inducing-button+button 6 (‘M’ is confirmed), button 3 (D, E, F), and the combination-inducing-button+button 7 (‘P’ is confirmed) and gives a signal that only a partial spelling of the word is entered, then the 4 places as based until button 3 will be confirmed almost as “HOME” (Of course, it can be more certain if each letter of the word ‘HOME’ is confirmed). Then, the system where if the device displays to the user the candidate words ‘HOMEPLATE’ and ‘HOMEPORT’ based on the letter ‘P’ that has been typed for confirmation then the user selects the desired ‘HOMEPORT’ becomes possible. Of course, it is possible to give an unknown letter signal while until typing in ‘P’ (E.g., in the place where button 3 is, it can be indicated that it is another unknown letter with “*” or another symbol).

If ‘P’ were not confirmed and a signal that the user entered only a partial spelling of the word is given, the device cannot know if button 7 is ‘P’, ‘R’, or ‘S’ even just in the state where ‘HOME’ is confirmed, and so all of the words that have ‘P’, ‘R’, and ‘S’ become candidate words. That is,

the user has to make a selection of the sought after word from among too many candidate words that have been displayed: HOMEPLATE, HOMEPORT, HOMER, HOMERANGE, HOMERIC, HOMERULE, HOMERUN, HOMESCHOOLING, HOMESCREEN, HOMESECRETARY, HOMESELLING, HOMESICK, HOMESIGAL, HOMESITE, HOMESPUN, HOMESTAND, HOMESTAY, HOMESTEAD, HOMESTEADER, HOMESTEADING, HOMESTRETCH, HOMESTUDY, etc.

The examples so far do not always take place without exception but for the purpose of explaining the concept only, the frequency, the candidate words displayed, etc. have been set randomly.

In existing methods such as the “T9 and others”, there would be many more actual candidate words since “HOME” was also not confirmed. When there are a lot of candidate words, a situation unfolds where one must hit the cursor moving button quite a lot if the desired word comes much later due to its alphabetical sequence or frequency.

And, even if it is a “T9 and others” typing method mode, not too much time is required if one were to make the entry after confirming the entire spelling of a given word as if the “T9 and others” typing method was not going to be utilized. Since typing in a given spelling by combining 2 buttons involves at any rate the use of both hands and the taking of responsibility for one button by each hand, if one becomes proficient at it, one can make the entry at a speed that is almost same as that of a single press of one button. Also, since the act of moving the cursor over to the sought after word among the displayed candidate words, which is essential in the method of typing a given spelling in such modes as the “T9 and others”], is not necessary, and what is required is making the selection as it is, the time needed to enter the necessary word can be shorter when compared to “T9 and others”.

Also, if every spelling is confirmed when typing, one can make a program by omitting the act of selecting itself.

In terms of “T9 and others”, an example of entering the word “HOMEPORT” will be provided while giving a comprehensive explanation of applying the present invention's method in parallel with existing methods. When the user seeks to type a certain word in the letter input mode of the “T9 and others”, he or she can do so for each spelling based on the existing method and the present invention's method or on other method which is similar to the present invention's methods, etc. without altering the mode and by combination. It is asserted that the method which possesses this as a feature also constitutes a part of the originality of the present invention's method.

(In existing “T9 and others”, when the word to be typed is not in the DB, there exists the inconvenience of having to shift to the multi tab mode, type in the sought after word, and return to the “T9 and others” mode. This is especially true for URLs, proper nouns, electronic mail addresses, various names of people, foreign words, technical words, etc.)

The “various methods” allowing for the typing in of letters so that abovementioned candidate words are displayed refer to the method that has been created by combining methods 1 and 2 below.

1. “AA” (Confirmed letter), or “BB” (Candidate letter), or “CC” (unknown letter) as letter types

2. “DD” (Total number of spellings) as the number of spellings to be typed and also a necessary component of constructing a word or “EE” (The number of incomplete spelling)

Although there are a lot of numbers in terms of possible combination of 1 and 2 such as AA+DD, AA+EE, BB+DD, BB+EE, CC+DD, CC+EE, AA+BB+DD, AA+BB+EE, BB+CC+DD, BB+CC+EE, AA+CC+DD, AA+CC+EE, AA+BB+CC+DD, AA+BB+CC+EE, etc, but in what follows, a few examples from among the cases that entail the typing of a simple text message and conducting a search will be given.

Let us take several detailed examples of composing a text message. (Let us also give an example of entering the word HOMEPORT. We will for now express it by taking the English alphabet for confirmed letter, numbers for candidate letter, and “*” for unknown letter.)

First, an existing “T9 and others” method which is a method of combining “BB” and “DD” when typing it.

(“46637678” is entered so that the candidate words can be displayed.

That is, it means that the entry is made in the form of button 4 (G, H, I), button 6 (M, N, O), button 6 (M, N, O), button 3 (D, E, F), button 7 (P, R, S), button 6 (M, N, O), button 7 (P, R, S), and button 8 (T, U, V). Hereafter, such a detailed explanation is omitted.)

Second, a method of combining “BB” and “EE” when typing them.

(One enters “46637” so that the candidates words are displayed and afterwards, gives the signal indicating the existence of incomplete spelling. As referred to earlier, the manufacturer or user can decide the case and method of giving the signal for the typed spelling, and since there are not that many candidates which includes the typed spellings in DB which has a small stored record such as telephone directory,

it seems better instead not to give a special signal when there is a spelling shortage but to do so only when the number of spellings is the same. Likewise, the same applies hereafter.)

Third, a method of typing after combining “AA” and “EE”

(One confirms it along with “HOMEP” and then types so that the candidates words are displayed and afterwards, give the signal indicating the existence of incomplete spelling.)

Fourth, a method of combining “AA” and “DD” and when typing them.

(Since one types in by confirming all spelling as “HOMEPORT”, only one candidate word exists and there is no need to make a selection.)

Fifth, a method of combining “AA”, “BB”, “CC”, and “DD” when typing them.

(One types “H6*EP67T” which conforms the number of spellings of search word to the number of spellings of desired word)

Sixth, a method of typing by combining “AA”, “BB”, “CC”, and “EE”.

(In order to have the candidate words displayed, one should give a signal for shortage of number of spellings after entering “H6*EP6” or give a signal for shortage of number of spellings after typing “*EP6”.)

Here, one more method is proposed for inputting search word by categorizing the random part of the sought after word as a differentiating letter, and this has to do with taking an example that, according to the “definition of terms”, “it can be set as a regulation that an unknown letter (“%” was given as an example below) can substitute for 2 or more consecutive letters”.

This method is useful because

first, in reference to English, one cannot know for sure based only on sound not only the spelling but also the number of spelling, but in such a case, one can use as a search word only the portion of the spelling that one knows for certain.

Second, this is because there is a tendency in English for a word to metamorphose into among others different parts of speech when a spelling change is made to the latter part of the word while the front part (=usually the root) remains unchanged. In this context, as one application example of the first method, one can type in the spelling by combining the methods from “AA” to “EE” by differentiating between the part that is not the last part of a word from its last part. Since an unknown letter can substitute for a letter made up of 2 consecutive letters, the unknown letter is used as a differentiating letter that separates the part that is not the last part of a word from its last part.

In other words, before entering the last part, one should give a signal such as a special symbol (E.g., %) indicating that the last part will be typed later and then type in the last part.

Among the words that contain ‘SENS’, there are SENSE, SENSEFUL, SENSELESS, SENSELESSLY, SENSIBILITY, SENSIBLY, SENSITIVE, SENSITIVITY, SENSITIZE, SENSOR, SENSORIAL, SENSORY, SENSUAL, SENSSUALITY, SENSUALLY, SENSUOUS, SENSUALIST, SENSSULISM, SENSUALIZE, SENSUALITY, etc.

If one looks at them carefully, it can be seen that the candidate words can be reduced by simply typing in the root letters ‘SENS’ and the last part of the word.

This is because for words found in English, there are many variations depending on the spelling of the latter part of the word.

If we consider several examples of the method of entering a search word when “SENSUALIST” is the word that is intended to be used.

As an example of the search word of the first method,

1. S % N % U % LIST

2. SE % SU %*7T

3. NS % AL and others can be used as search words to generate candidate words that contain “SENSUALIST”.

As an example of the search word of the second method,

1. SENS % IST

2. 7367%478

3. S3*7%*7T

4. S3*7%7T

5. S3*7% T

6. S3*7%8

7. 3*7%8 and others can be entered to generate candidate words that contain “SENSUALIST”.

Moreover, like above, in terms of the method of typing the spelling by combining from the above “AA” to “EE”, it can be utilized usefully when entering letters to search for an item in a DB that has a significantly less number of stored record (The term record is easily understood if it is thought of as a phrase composed of two or more words) than a language dictionary such as the telephone directory on a cell phone.

Because the number of records is small, it is also useful when searching for a record that is made up of several words since the number of candidate records is small.

Since, irrespective of whether there are many or few letter buttons, this method can sometimes be useful when the number of records is small, it can be said that it is of use for such devices as a computer keyboard which has many buttons. And of course, it can also be applied to the method of improving the “T9 and others”. In what follows, let us learn about the method of application.

1. A method of entering a letter when there is one spelling per letter (or cursor) as in

English

Several examples of searching for ‘VOLFGANG AMADEUS VON MOZART’ shall be considered.

Here as well, it is shown by taking an example of the English alphabet as a confirmed letter, a number as a candidate letter, and “*” as an unknown letter.

If it is actually a number, then this is indicated by adding a “/” before or after the number.

A space in writing will be indicated as it is, that is as a space in writing.

The differentiating letter between letters is indicated with a comma (,) or ‘#’.

In actual application, one can substitute another symbol for the unknown letter, or actual number, or a space in writing, or the differentiating letter between letters.

First, a method of typing with “BB” and “DD” combined

For example, in order for the candidate records to be displayed, one enters the candidate letter by conforming a complete number of spellings to the selected word by selecting one or more search words among each of the words in the stored record that would be ultimately selected (One types in “661278” to conduct a search with the word, MOZART, or one types “2623387 866” to carry out a search with the word, AMADEUS VON).

Second, a method of typing with “BB” and “EE” combined

For example,

Only the first letter of each word is entered (After entering “8 2 8 6”, give a signal indicating that there is a word with incomplete spelling).

Or, one types in more than the first letter of each word (After entering “86 26 8 661”, give a signal indicating that there is a word with an incomplete spelling).

Or, one enters only a portion of the word that is sought after. Here, in order to make a search using EUS of AMADEOUS, one enters “387” and then gives a signal indicating that there is a word with an incomplete spelling.

Third, a method of typing by combining “AA” and “EE”

For example,

One types by confirming the first letter of each word (After entering “V A V M”, give a signal indicating that there is a word with an incomplete spelling).

Or, one types by confirming more than the first letter of each word (After entering “VO AM V MOZ”, give a signal indicating that there is a word with an incomplete spelling).

Or, in order for the candidate records can be displayed, one enters the confirmed letter by conforming an incomplete number of spellings to the selected word by selecting one or more search words among each of the words in the stored record that would be ultimately selected (In order to conduct a search using only the word, MOZART, give a signal indicating that there is a word with incomplete spelling after entering “MOZ”).

Fourth, a method of typing by combining “AA” and “DD”

For example, in order for the candidate records to be displayed, one enters the confirmed letter by conforming a complete number of spellings to the selected word by selecting one or more search words among each of the words in the stored record that would be ultimately selected (In order to conduct a search using the word, MOZART, enter “MOZART”, or enter “AMADEUS VON” to carry out a search for “AMADEUS VON”).

Fifth, a method of typing by combining “AA”, “BB”, “CC”, and “DD””

For example, in order for the candidate records to be displayed, one enters the confirmed letter, or candidate letter, or unknown letter by conforming a complete number of spellings to the selected word by choosing one or more search words among each of the words in the stored record that would be ultimately selected (In order to conduct a search using the word, MOZART, enter “M6*2*T”, or enter “A6*3E8S or, “V*6” to carry out a search for “AMADEUS VON”).

Sixth, a method of typing by combining “AA”, “BB”, “CC”, and “EE”.

For example, in order for the candidate records to be displayed, one enters the confirmed letter, or candidate letter, or unknown letter by conforming an incomplete number of spellings to the selected word by choosing one or more search words among each of the words in the stored record that would be ultimately selected (In order to conduct a search using the word, MOZART, one enters “M6*2”, or one enters “A6*3E V*” to carry out a search for “AMADEUS VON” and then gives a signal to indicate that there is a word with an incomplete spelling. Or, in order to make a search for the word, “EUS VON”, one enters “*8S V*” and then gives a signal indicating that there is a word with an incomplete spelling).

2. A method of entering a letter for a language like Korean, Chinese, or Japanese which has a unique sound for each letter (Usually, one cursor is allotted; hereafter, ‘letter’ will often denote ‘unique character’) and in making that sound, a combination of one or more alphabet spelling is used.

(For Chinese, Japanese, etc. characters unique to the country is contained in the content of the record field, and it is possible when those unique characters are automatically interpreted as a pinyin sign that is similar to the English alphabet.

What this means is that, similar to example ‘3’ that appears several paragraphs later, this is possible when one assumes that when searching the DB with [symbol] using pinyin symbols similar to the English alphabet, this is automatically taken to be ‘JUNG,HWA,MIN,GUK DE,TONG,LIONG’ and then searched accordingly within the device.

For Korean, this should be applied by regarding that it becomes a pinyin as a Korean phoneme alphabet.

(The only difference from English in respect to entering a search word is that when typing in one letter, one can give an indication of dividing into a unit of letters using a differentiating letter when typing in several different spellings.

In the explanation give below, comma was taken as a differentiating letter between letters, signaling that the number of spellings entered as a search word can be smaller than the number of spellings of the desired unique character (In Korean, if one types the initial sound, it becomes obvious that there is a change of letter, and so a differentiating letter does not need to be used), # was selected as the differentiating letter between letters when the number of spellings is the same as the unique character. However in the above two cases, any symbol (including an absence of differentiating letter or a blank) can serve as a differentiating letter.

In the above, a blank was utilized as the differentiating letter between words as well, if the differentiating letter between letters was one blank, then the differentiating letter between words can be two blanks or another symbol.)

With an example of searching for ‘□□□ □□2□□□’ and [symbol] , the above third and sixth English example will be given as a case study.

(Here as well, Korean, the alphabet as confirmed letter, numbers as candidate letter, “*” as unknown letter are taken as examples and expressed accordingly. For actual numbers, they will be indicated with a “/” either before or after the number. A space will be shown in actuality as a space. The differentiating letter between letters shall be shown with either a comma or ‘#’. In actual application, one can substitute another symbol for the unknown letter, or actual number, or a space in writing, or the differentiating letter between letters.

Third, a method of typing by combining “AA” and “EE”.

For example,

One confirms the first letter of each word and then types.

(After entering “□ □ □”, one gives a signal indicating that there is a word with an incomplete spelling. After typing in “J D”, one gives a signal indicating that there is a word with incomplete spelling.)

Also, type after confirming more than the first letter of each word.

(Enter “□□□ □□ □□” or “□,□,□ □,□ □,□” and give a signal indicating that there is a word with incomplete spelling.

Enter “JHMG DTL”, “J,H,M,G D,T,L”, or “J,H D,T,L” and then give a signal indicating that a word with incomplete spelling exists.)

If considering a reverse concept,

after a consecutive spelling, if there is a differentiating letter between letters

such as a comma, a signal that a consecutive spelling was sequentially entered from the random position of the random character unit location derived from the unique character of the sought after word set as a pinyin will be given,

and if there is no comma, a signal that only the first alphabet of the alphabet corresponding to each unique character derived from the unique character of the desired word set as a pinyin will be given. Such a logic is also possible.

For example,

Since “JHMG,” or “JH,” has a comma at the end, each alphabet is regarded as the alphabet derived from the Chinese characters that are set as a pinyin being entered sequentially, and as such, it is not possible to search for ‘JUNG,HWA,MIN,GUK DE,TONG,LIONG’. A search is possible if a comma is given after an alphabet that continues on as in “JUN,” or “JUN,H” or “JUN,H,MIN” from a random position of a random character unit location.

Since there is no comma after “JHMG” or “JH”, the ‘JUNG,HWA,MIN,GUK DE,TONG,LIONG’ search is possible by regarding each alphabet as an alphabet that continues on from the random position of the random character unit location of a Chinese character that is set as a pinyin.

The same is true hereafter.)

Or, in order to display the candidate records, one needs to select more than 1 search word from among each of the words of the record to be ultimately selected, and in respect to the selected words, one enters the confirmed letter according to the number of incomplete spelling.

(In order to conduct a search only with the word, “□□□”, one should give a signal that there is a word with incomplete spelling after entering either “□□” or “□□□”.

To conduct a search with only “DE,TONG,LIONG”, one should give a signal that there is a word with incomplete spelling after entering only “D,T”, or “D,T,L”, or “DTL”.)

Also, even while trying to search for “□” but only intending to enter its partial form, “□”, one should give a signal that there is a word with incomplete spelling after entering “□□□” or “□,□,□” or one should give a signal that there exists a word with incomplete spelling after typing in “□□”, or “□,□”, or “□□□”, or “□,□,□”.

Also even while searching for “TONG” but only intending to enter its partial form, “TO”, one needs to give a signal indicating that a word with incomplete spelling exists after typing “D,TO,L”.

If because of “□”, a situations arises where “□” should not be searched, then one needs to give a signal indicating that there is a word with incomplete spelling because of “□” or “□” after entering “□□#”, or “□,□#”, or “□□#□”, or “□,□#□”, or “□,□*#□” by using “#”, which is a sign indicating that the number of spelling is same as that of “□”, as a differentiating letter.” In such a context, one is unable to search for “□”, and the result is that “□□□ □□2□□□” cannot be searched.

If because of “TO” a situations arises where “TONG” should not be searched, then one needs to give a signal indicating that there is a word with incomplete spelling because of “D” or “L” after entering “D,TO#L” by using “#”, which is a sign indicating that the number of spelling is same as that of “TO”, as a differentiating letter.” In such a context, one is unable to search for “TONG”, and the result is that “JUNG,HWA,MINGUK DE,TONG,LIONG” cannot be searched.

Sixth, a method of typing by combining “AA”, “BB”, “CC, and “EE”.

For example, in order to display the candidate records, one needs to select more than 1 search word from among each of the words of the record to be ultimately selected, and in respect to the selected words, one enters the confirmed letter, or candidate letter, or unknown letter according to the number of incomplete spelling (To search with the word, “□□□”, one gives a signal indicating that there is a word with incomplete spelling after entering “□*5”, “□,*□,5”, “□,□*□#5”).

Also, to search with the word, “□□□ 58 □2”, one should give a signal indicating that a word with incomplete spelling exists after entering “*□8*□2/” (‘/’ shows that ‘2’ is not a candidate letter but an actual number).

To perform a search with the word “DE,TONG,LIONG”, one should give a signal indicating that a word with incomplete spelling exists after typing in “D,*,5”, or “DE,T*N,5”, or “DE,TO*4#5”, or “*E,TO*G#,L*6”).

3. It can be utilized when one makes an entry and a search by applying more than one differentiating letter in the middle of a word from the outset. Although one can apply this to a language that is similar to English, there are only a few gains of utilization in doing so. This is a method where like Chinese, if there is a unique sound to each unique letter, when one enters that sound as a pinyin and others that are similar to the English alphabet, one types the search word in accordance with the input form used at the time of searching after typing in by applying a differentiating letter at a position of the unique character unit or position preferred by the user.

For example, although one does not know how to read [symbol] in Chinese but if one were to assume that it is read as ‘JUNGHWAMINGUK DETONGLIONG’, and let us say that when the user stores it in the DB, he or she thinks about doing so not in Chinese but as ‘JUNGHWAMINGUK DETONGLIONG’, which is a pinyin form. However, for the purpose of ensuring an easy search later on, the user utilizes a comma, which is a differentiating letter between letters, and enters ‘JUNG,HWA,MINGUK DE,TONG,LIONG’. The ‘MINGUK’ of ‘JUNGHWAMINGUK’ is typed without any differentiating letter.

Although there are many methods of entering a search word so that ‘JUNG,HWA,MINGUK DE,TONG,LIONG’ is displayed as a candidate to be selected, in what follows, the third and sixth example among the examples of above English mentioned earlier will be looked at (Here as well, it is shown by taking an example of the English alphabet as a confirmed letter, a number as a candidate letter, and “*” as an unknown letter. If it is actually a number, then it is indicated by adding a “/” before or after the number. A space in writing will be indicated as it is, that is as a space in writing. The differentiating letter between letters is indicated with a comma (,) or ‘#’. In actual application, one can substitute another symbol for the unknown letter, or actual number, or a space in writing, or the differentiating letter between letters).

Third, a method of combining “AA” with “EE” for typing

For example,

One enters the only the first letter of each word which is confirmed (Give a signal that indicates that there is a word with incomplete spelling after entering “J D”).

Or, confirm more than the first letter of each word and then enter (Give a signal indicating that there exists a word with incomplete spelling after typing “J,H,M,D,T,L”).

In order for the candidate records to be displayed, one enters the confirmed letter in accordance with the number of incomplete spelling in respect to the selected word by selecting one or more search words among each of the words in the stored record that would be ultimately selected.

(To carry out a search with only the word, “JUNG,HWA,MINGUK”,

One gives a signal indicating that a word with incomplete spelling exists after entering “J,H” or “J,H,M”.

Also, even while trying to search for “MINGUK” but only intending to enter its partial form, “MING”, one should give a signal that there is a word with incomplete spelling after typing “J,H,MING”, or one should give a signal that there exists a word with incomplete spelling after typing in “H,MING” or “HW,MING”.

If because of “MING”, a situations arises where “MINGUK” should not be searched, then one needs to give a signal indicating that there is a word with incomplete spelling after entering “J,H,MING#” or “JUN,H,MING#” by using “#”, which is a sign indicating that the number of spelling is same as that of “MING”, as a differentiating letter.

Even in such a situation, “MINGUK” cannot be searched and as a result, ‘JUNG,HWA,MINGUK DE,TONG,LIONG’ is not able to be searched.

Sixth, a method of typing after combining “AA”, “BB”, “CC”, and “EE”.

For example, in order for the candidate records can be displayed, one enters the confirmed letter, or candidate letter, or unknown letter by conforming an incomplete number of spellings to the selected word by choosing one or more search words among each of the words in the stored record that would be ultimately selected.

(In order to make a search with the word, “JUNG,HWA,MINGUK”, one gives a signal indicating that there is a word with incomplete spelling after typing in “J,*,6”, or “JUN,H*A,6”, or “JUNG,**A#6”, or “JUNG,A,6”, etc.)

And it is possible to maximize the number of the signal that can be created by the single hit or combining with another button by utilizing a combination-inducing-button (It is possible to designate two or more combination-inducing-buttons that perform the same function).

By signal, it is here meant not just a function that allows for the typing of letters, but other functions are also possible. The fingers getting in each other's way at this time because the two buttons that need to be hit are placed consecutively in a vertical fashion will not be considered.

When applying to a device, it is possible to utilize it by making a distinction between a situation where two or more combination-inducing-buttons (or a button that has been set as a combination-inducing-button) that each carries out a function different from each other are switched on before the letter button and a situation where the combination-inducing-buttons are switched on later. It is also possible to generate another signal when one combination-inducing-button is made to be switched on after the letter button (This is especially true when setting a button to which no letter is allocated as a combination-inducing-button, as explained below).

The greatest reason for trying to maximize is because the letters that need to be allocated to the buttons according to the country is more than in the case of English which has 26 so that a situation arises where more than three letters need to be assigned to a single button, one needs to deal with the inconvenience of having to hit the same button several times and with the continued inconvenience that remains even after improving the method of input in order to select a specific letter.

This is because each country has a different number of necessary letters, such as 33 for Russia, 30 for Bulgaria, 46 for Hindi, 50 for Japanese, 44 for Myanmarese, 46 for Hindi, 76 for That (in reality, only 62 are needed), etc. [[[[[, and there are cases where the number of letters is quite a lot. □□ □□□□]]]]] To help one understand the table below, let take an example where letters are allocated only to nine buttons like the English alphabet and no letters assigned to ‘*, 0, and #’.

At this stage, it was intended that a single hit allows for the writing of the first letter allocated to each button, ‘*’ functions as a combination-inducing-button that allows for the typing of second letter allocated to each button (Of course, this is possible with a double click), ‘0’ functions as a combination-inducing-button that allows the writing of the third letter allocated to each button (Of course, this is possible with a triple click. Hereafter, sentences in parenthesis are omitted), and ‘#’ functions as a combination-inducing-button that permits the display on the screen of the fourth letter assigned to each button. It was likewise intended to set buttons 1˜9 as combination-inducing-buttons but letters are already allocated to them, which means that it is necessary to assign two or more combination-inducing-buttons that have the same function, that is the function of typing letters of specific sequence allocated to that button. And as such, if the nine in 1˜9 are divided by two, it becomes 4.5, and if cut, it becomes 4.

In this way, with eight of buttons 1˜9, one can designate two sets of combination-inducing-buttons that allow for the typing of the 5th, 6th, 7th, and 8th letter allocated to each button, and one is left as a spare. Then, it is possible to assign eight letters to one button, and since such buttons amount to nine, it becomes possible to type a total of 72 as a single hit or as a combination of two buttons by allocating them to buttons 1˜9. Until now, the existing method made the user hit the same button eight times to type the 8th letter.

Now, let us look at a general example from a more mathematical point of view.

‘A’ shall be regarded as ‘the number of buttons to which letters are allocated’ (The example explained earlier is A=9), and

‘B’ will be regarded as ‘the number of buttons to which no letter is allocated’ (The example explained earlier is B=3), and

‘D’ will be viewed as ‘the number of letters that are possible to be assigned to a single button’, and

D=B+Cut(A/2)+1 (The example explained above is, D=3+Cut(9/2)+1=8).

If ‘E’ is regarded as ‘the total number of letters that are possible to be allocated, then

E=A*D (The example explained earlier is, E=9*8=72)

If one were to express the number of situation A, B, D, and E in a table format, it would look like something like the following.

| | | | D | E |
|---|---|---|---|---|
| sequence | A | B | (=B + cut(A/2) + 1) = D | A * D = E |
| 1 | 2 | 10 | 10 + cut(2/2) + 1 = 12 | 2 * 12 = 24 |
| 2 | 3 | 9 | 9 + cut(3/2) + 1 = 11 | 3 * 11 = 33 |
| 3 | 4 | 8 | 8 + cut(4/2) + 1 = 11 | 4 * 11 = 44 |
| 4 | 5 | 7 | 7 + cut(5/2) + 1 = 10 | 5 * 10 = 50 |
| 5 | 6 | 6 | 6 + cut(6/2) + 1 = 10 | 6 * 10 = 60 |
| 6 | 7 | 5 | 5 + cut(7/2) + 1 = 9 | 7 * 9 = 63 |
| 7 | 8 | 4 | 4 + cut(8/2) + 1 = 9 | 8 * 9 = 72 |
| 8 | 9 | 3 | 3 + cut(9/2) + 1 = 8 | 9 * 8 = 72 |
| 9 | 10 | 2 | 2 + cut(10/2) + 1 = 8 | 10 * 8 = 80 |
| 10 | 11 | 1 | 1 + cut(11/2) + 1 = 7 | 11 * 7 = 77 |
| 11 | 12 | 0 | 0 + cut(12/2) + 1 = 7 | 12 * 7 = 84 |

(In the above table, when one seeks to use a button to which no letter is allocated as a combination-inducing-button,

if a distinction is made between a situation where

the letter button to which letter is allocated switches on before combination-inducing-button (=a button to which no letter is allocated) and

the letter button to which letter is allocated switches on after combination-inducing-button (=a button to which no letter is allocated),

the result will be D=2B+Cut(A/2), which means that a greater number for D or E will be deduced.)

To put in extreme terms, it is possible to apply the sequence 2 method in terms of the 26 English alphabet.

The reason for this is because, by allocating eleven letters to each of three buttons, one can designate as a single hit that allows the typing of the first letter allocated to a button, as combination-inducing-buttons enabling the entry of the 2nd to 10th letters the nine buttons to which no letter is assigned, and as combination-inducing-buttons allowing the typing of the 11th letter two of the three buttons to which letters are allocated.

This aspect can also be considered as a strength when compared to the “T9 and others”. This is because with the “T9 and others”, the higher the number of spelling allocated to one button, the greater the exponential growth of candidate words will be, which will make it practically impossible for the device to be used. Of course, the same is true for the signals of other languages and others.

One can also make an extreme application of sequence 2 method by regarding Korean language as having 33 letters. The 33 letters in Korean refer to 14 basic consonants (□□□□□□□□□□□□□□), 5 fortises (□□□□□), 10 basic vowels (□□□□□□□□□ □), and 4 expand vowels (□□□□) (However, for Korean, one sometimes adds more expanded vowels and says that there are 40 or some other figures, as shown later. As such, the number varies according to the type of categorization).

The 62 letters in That language can be expressed by applying the above method found from sequence 6 to 11. This is because the value of ‘E’ of sequence 6 to 11 is more than 62. What is meant by applying the method of sequence 6 is that one is able to allocate 9 letters each to each of 7 buttons so that 63 letters can be used as a single hit or in combination with another combination-inducing-button. And the meaning of applying sequence 11 is that one can assign 7 letters each to each of 12 buttons and utilize 84 letters in a single hit or in combination with another combination-inducing-button. Of course, the user can allocate 5 or 6 letters each to each of 12 buttons and use 62 letters as a single hit or in combination with another combination-inducing-button.

Also, in respect to English, if one wants to type by allocating 3 capital letters, 3 small letters, and 1 number to one button with no mode alteration, then one could apply the method found in sequence 6 to 11. This is because when one adds a total of 26 capital letters, a total of 26 small letters, and a total of 10 numbers and obtain 62, which is identical to That. However, sequence 8 is most highly recommended. The reason for this is because based on sequence 8, one can actualize an ordinary English keyboard as it is.

To provide a comprehensive conclusion for cell phones, if the present invention's method is applied, cell phone manufacturers can configure the buttons based on a method that maximizes convenience and efficiency, in the form of pursuing frequency of use of letters, relationship with vowels and consonants, even utilization of right and left hands, etc.

3. Digital Camera

A digital camera does not have ordinary letter buttons but has only function keys.

A function button, even if it is a button in the same position,

its function could differ depending on what the present mode is (E.g., the right direction key becomes a toggle button that indicates the on/off status of the flash light in the picture taking mode and plays the role of shifting to the next picture in the mode that enables the user to see on the display the pictures already taken).

If there is no operation relating to the present mode, nothing happens even when the button pressed (E.g., the down button moves the cursor downwards in the menu mode but has no function in the mode for looking at pictures).

It sometimes carries out the same operation irrespective of the current mode (E.g., the power button becomes a toggle button that always either switches the camera on or off irrespective of the current mode).

The problem is that each button carries out an operation immediately after it is switched on so that one cannot designate a new operation by combining one button with another.

If like the example of applying the present invention to a computer (Esc button and Home button), if a certain function button, in addition to its original function, has been designated in advance to perform another operation via the combination of another button switching on before that function button switches off after having been switched on, one can carry out another operation when a button to which is allocated another operation and which completes a combination switches on before that function button switches off after having been switched on. And one can set it up in such a way that if the button to which is allocated another operation and that completes a combination does not switch on before that function button turns off after switching on, the function button carries out its original operation. In doing this, a button that used to be able to carry out just one function in one mode can perform a variety of operations by a combination of buttons.

Last, several practical examples of allocating a letter to a button in respect to Korean and English will be considered.

First, let us look at the frequency of use of Korean and English alphabet.

(Though it differs slightly depending on the data used to come up with statistics, for most cases, the figures are very similar.)

The reason for trying to find out the frequency is that when allocating a letter, by assigning the one with high frequency of use in a higher sequence than the several letters that will be allocated to buttons, one can type effectively even in the multi tab mode. And, even according to the present invention's method, the letter that is allocated at first is entered as a single hit and not in a combination mode and from the second letter, one can type in by combining buttons. As such, the higher the number of single hit entries, the greater the increase there is in terms of the effectiveness of the present invention.

1. The frequency of use for Korean (From high frequency of use to low frequency of use)

Consonants (19): □,□,□,□,□,□,□,□,□,□,□,□,□,□,□,□,□,□,□

Single vowels (10): □,□,□,□,□,□,□,□,□,□ (However, the frequency of vowels is not necessarily important because only one gets allocated to each of the 10 buttons of 0˜9 since there are only 10.)

Multiple vowels (11): □,□,□,□,□,□,□,□,□,□,□ (This can be allocated by pairing with other letters similar in form to the single vowels and others, and as such, the frequency is not important. Hence, this is not arranged according to the frequency sequence.)

2. The frequency of use for English alphabet (From high to low frequency)

26: Several results exist according to different statistical agencies.

E, T, A, O, S, N, I, R, H, D, L, C, M, U, P, F, G, W, Y, B, V, K, X, J, Q, Z (applied to the example below)

E, T, A, O, I, N, S, R, H, L, D, U, F, M, W, Y, G, P, C, B, V, K, X, J, Q, Z

E, T, O, A, N, I, R, S, H, D, L, U, C, M, P, F, Y, W, G, B, V, K, J, X, Z, Q

Next, let us think about allocation of Korean.

Even if several letters are allocated to one button as based on the present invention's methods, one can type in one beat with both hands based on the combination of 2 buttons, and as such,

even if 4 of 19 consonants, 10 single vowels, and 11 multiple vowels, which is a total of 40, are allocated to each of 0˜9 buttons, the user can type in one beat (=2 hits based on a combination), which is much quicker than in existing method of typing. Also, very few typing errors will occur while entering multiple vowels, which is the most difficult part in Cheonjiin method of typing vowels (E.g., while trying to enter ‘□’, one types ‘□ □ □’).

Also, approximately 2 special characters can be additionally assigned to each button that is used more frequently.

Let us now consider an example of the method of entering 6 letters allocated to each button (4 Korean characters and 2 special characters) as follows (If the total number of characters and special characters add up to 6, then it is applicable to any language in the same way as shown below).

It is possible to type in the first letter in a single hit (In the type in mode of “T9 and others”,

when one types in a letter as a confirmed letter,

the combination inducing button is switched on before the button to which the desired letter is allocated,

that is, one designates button 1 and button 3 as a preceding combination-inducing-button that permits the typing in of the first letter of a given button), and

one designates button 4 and button 6 as a preceding combination-inducing-button that allows the entering of the second letter, and

one designates button 7 and button 9 as a preceding combination-inducing-button that permits the typing of the third letter, and

one designates button * and button # as a preceding combination-inducing-button that allows the entering of the fourth letter (If no letter is allocated to button * and button #, and if one does not mind fingers getting in each other's way or the broadening of the scope of finger movement, one can designate buttons * and # as combination inducing keys that carry out functions that differ from each other.), and

one designates button 2 and button 8 as a preceding combination-inducing-button that allows the typing of the first special character, which is the sixth letter (Or, since the frequency of use of the special characters is low during an ordinary use of the keyboard, and because there is a need for only one combination-inducing-button if one does not take into account the fingers getting in each other's way, one can set button * as a succeeding combination-inducing-button. This is possible when no letter is designated to button *.), and

one designates button 5 and button 0 as a preceding combination-inducing-button that allows the typing of the second special character which is the sixth letter (Or, since the frequency of use of the special characters is low during an ordinary use of the keyboard, and because there is a need for only one combination-inducing-button if one does not take into account the fingers getting in each other's way, one can set button # as a succeeding combination-inducing-button. This is possible when no letter is allocated to button #.),

and last, one can designate button * and button # as a succeeding combination inducing button that allows the entering of a number allocated to a certain button. This is possible when no letter is allocated to button * and button #.

Of course, as above

in terms of entering 1st to 6th letter with multitap method, that is, based on the number of consecutive hitting of the key,

one can employ existing methods as well such as entering a number with a long press.

A single hit of button * and button # will perform another function (existing function: e.g., alteration of letter mode, addition of the order of making strokes when writing a Korean, etc.).

If a letter is allocated to button * or button # as well,

Because one cannot type letters using a combination button using methods that have been commercialized thus far, a maximum of 10 letters can be entered in a single hit if letters are allocated only to the 10 buttons, 0˜9, and since * or # are operated only as a single hit, they could be used only as a special function key such as for the purpose of changing the letter mode. However, if made to carry out its function through combination button, one can enter as many as 12 letters in single hits by actively assigning a letter to * or # so that letters are allocated to 0˜9, *, and #.

Until now, * and # carry out certain functions through single hits in the letter writing mode as function buttons, but in reality have lower rate of use than the letter buttons when one writes letter. Thus, it becomes more efficient by allocating a letter to that button as a priority and to substitute the function that is performed with a single hit so that it is carried out by combining * or # with a combination-inducing-button or by multiple hits and then make it write letters as a priority.

At this time, if the user does not want to set it as a combination button that requires the use of both hands, he or she can set it as a multi tab mode that uses only one hand, but if one tries to perform the existing function of * or # via the multi tab, because a letter gets typed first as letters are already allocated to * or #, it is more efficient to employ it as a combination button. If one wants to make even both hands to carry out the function of * or # button, one can designate any letter button as a combination-inducing-button, however,

to make it also possible with one hand, by additionally designating the volume control button, internet connect button, etc., which provides no response, as a combination-inducing-button that has the same function, one can make it carry out the existing function of * or # button when * or # button switches on before a combination-inducing-button such as the volume control button or internet connect button switches off after having been switched on or after it switches off having been switched on. Or one can make it carry out the same function when a combination-inducing-button like the volume control or internet connect button turns on before * or # button switches off after switching on or after it switches off having been switched on. If not, it can also be designated that the volume control button or internet connect button simply carries out the existing function of the * button or # button.

In reference to English, since it does not have that many alphabets and has fewer vowels than Korean, in order for one to enhance convenience when entering letters via the multi tab mode, even while taking the frequency of letter use into consideration, and because the very first allocated letter can be typed in as a single hit rather than by a combination based on the present invention's method, the following consideration is made.

1. By considering only the frequency, allocation of the first, second, and third letter to the buttons was tried, and

2. If only the frequency is considered, the user could become confused because it differs significantly from the widely recognized button layout found on telephone varieties, and as such, the already commercialized allocation combination is retained as much as possible while allocating the sequence based on the order of frequency observed only within that button. (If among the letters allocated to each button, when one marks with a different color or others the first in the sequence found in the alphabet memorization song, then it would be better for the user when trying to recognize from which to which alphabet one finds allocated to that button. In the example given below, it will be indicated as capital letters.)

3. In the case where ‘N’, ‘M’, and ‘O’ are allocated simultaneously to the same button, it was tried here to assign ‘NM’ and ‘O’ separately since the frequency of use for ‘N’ and ‘O’ is extremely high (This is because the rate of use for ‘O’ is higher than ‘N’ and ‘N’ is higher than ‘M’).

In the case where ‘P’, ‘Q’, ‘R’, and ‘S’ are allocated simultaneously to the same button, it was tried here to assign ‘PQR’ and ‘S’ separately since the frequency of use for ‘R’ and ‘S’ is extremely high (Although the frequency of use for ‘R’ can be either higher or lower than ‘S’, but it is higher than ‘P’ or ‘Q’).

4. Like Tables 1-6 or Tables 2-5 that appear later, letters were allocated to * or # button.

The advantages of allocating a letter to * or # button and a proposal to solve elements of inconvenience in existing devices have been described earlier in the Korean example, and hence, a detailed explanation will not be given.

Allocation patterns found in Table 1-6 are also advisable, because the first letter assigned to each button, excluding ‘W’, makes up 11 most frequently used items.

The reason that capital letters are not used even when ‘I’ is allocated as the first letter is because capital ‘I’ can be confused with small letter ‘l’. In actuality, in another case where only one letter is allocated to a button (D,I,O,S in Table 1-6), the user cannot become confused over the letter allocated to that button, whether or not it is a capital or small letter. This is because there is only 1 letter.

5. And

since the frequency ranking of ‘P,Q,R,S,T’ can be either ‘T,S,R,P,Q’ or ‘T,R,S,P,Q’ and

the frequency ranking of ‘V,W,X,Y,Z’ can be either ‘W,Y,V,X,Z,’ or ‘Y,W,V,X,Z’,

in the table below,

what was allocated in ‘Wyx’ sequence can be changed to ‘yWx’, or

what was allocated in ‘srP’ sequence can be changed to ‘rsP’, or

what was allocated in ‘srPq sequence can be changed to ‘rsPq’, or

what was allocated in ‘Wyxz’ sequence can be changed to ‘yWxz’,

To put differently, it means that it will be arranged according to frequency irrespective of the country of origin of the letters.

Though somewhat more inefficient than the present proposal for improvement, it would be better than existing button allocation made according to the manufacturer even if the combination of letters are allocated to the buttons should be made according to the present proposal for improvement and the sequence of the letter allocated to each button is set according to the sequence found in the Alphabet Song (E.g., the present proposal for improvement-UK and Alphabet Song sequence-JKL).

**An example of a comparison of English letter allocation in existing method and in the present invention

| 1 qz | 2 abc | 3 def |
|---|---|---|
| 4 ghi | 5 jkl | 6 mno |
| 7 prs | 8 tuv | 9 wxy |
| * | 0 | # |

* Existing Samsung Mobile Phone

| | | | | | | | |
|---|---|---|---|---|---|---|---|
| 1-1 | 1 Qz | 2 Acb | 3 eDf | 1-2 | 1 Qz | 2 Acb | 3 eDf |
| | 4 ihG | 5 lkJ | 6 onM | | 4 ihG | 5 lkJ | 6 nM |
| | 7 srP | 8 Tuv | 9 Wyx | | 7 O | 8 srP | 9 Tuv |
| | * | 0 | # | | * | 0 Wyx | # |
| 1-3 | 1 Acb | 2 eDf | 3 ihG | 1-4 | 1 Acb | 2 eDf | 3 ihG |
| | 4 lkJ | 5 onM | 6 rPq | | 4 lkJ | 5 nM | 6 O |
| | 7 tSu | 8 wVx | 9 Yz | | 7 rPq | 8 tSu | 9 wVx |
| | * | 0 | # | | * | 0 Yz | # |
| 1-5 = | 1 Acb | 2 eDf | 3 ihG | 1-6 = | 1 Acb | 2 D | 3 Ef |
| 2-4 | 4 lkJ | 5 nM | 6 O | 2-5 | 4 hG | 5 i | 6 lkJ |
| | 7 rPq | 8 S | 9 Tuv | | 7 nM | 8 O | 9 rPq |
| | * | 0 Wyxz | # | | * S | 0 Tuv | # Wyxz |

* A Proposal for Improvement for Samsung Mobile Phone

| | | |
|---|---|---|
| 1 | 2 abc | 3 def |
| 4 ghi | 5 jkl | 6 mno |
| 7 pqrs | 8 tuv | 9 wxyz |
| * | 0 | # |

* Existing LG Mobile Phone

| | | | | | | | |
|---|---|---|---|---|---|---|---|
| 2-1 | 1 | 2 Acb | 3 eDf | 2-2 | 1 Acb | 2 eDf | 3 ihG |
| | 4 ihG | 5 lkJ | 6 onM | | 4 lkJ | 5 onM | 6 srPq |
| | 7 srPq | 8 Tuv | 9 Wyxz | | 7 Tuv | 8 Wyxz | 9 |
| | * | 0 | # | | * | 0 | # |
| 2-3 | 1 Acb | 2 eDf | 3 ihG | 2-4 | 1 Acb | 2 eDf | 3 ihG |
| | 4 lkJ | 5 nM | 6 O | | 4 lkJ | 5 nM | 6 O |
| | 7 srPq | 8 Tuv | 9 Wyxz | | 7 rPq | 8 S | 9 Tuv |
| | * | 0 | # | | * | 0 Wyxz | # |
| 2-5 | 1 Acb | 2 D | 3 Ef | | | | |
| | 4 hG | 5 i | 6 lkJ | | | | |
| | 7 nM | 8 O | 9 rPq | | | | |
| | * S | 0 Tuv | # Wyxz | | | | |

* A Proposal for Improvement for LG Mobile Phone

It is reminded here that all of the examples given until now should be taken simply as examples and not as providing a comprehensive overview of the present invention's method. A professional in this field would be able easily to make alteration, adjustment, and combination based on the explanations provided above.

And while all of the methods suggested in this invention can be set on a device at the discretion of the manufacturer, a device can be made in such a way that a non manufacturer can also do so in accordance with his or her convenience.

While preparing this application form, I could not formulate the Claims in a consistent manner, but in what follows, a categorization and sequential list of the Claims are given for the purpose of providing consistency.

1. Claims that will be more effective when applied primarily to telephone varieties

80, 38, 5, 6, 7, 65, 20, 21, 8, 9, 52, 10, 11, 12, 13, 14, 15, 16, 17, 18, 19, 88, 60, 22, 23, 24, 94, 83, 84, 25, 26, 27, 28, 29, 30, 31, 61, 62, 63, 64, 53, 75, 76, 77, 78, 89, 90, 91, 79, 85, 86, 87, 54, 55, 56, 57, 58, 59, 74, 51, 1,2, 3,4, 40, 41, 42, 43, 48, 49, 50, 67

2. Claims that will be more effective when applied primarily to calculators

66

3. Claims that will be more effective when applied primarily to computer keyboards

68, 81, 92, 82, 37, 80, 5

4. Claims that will be more effective when applied primarily to toggle keys: 69, 70, 71, 72, 73, 95

### MODE FOR THE INVENTION

•

### INDUSTRIAL APPLICABILITY

•

### SEQUENCE LISTING

•

1.-95. (canceled)

96. In terms of the method of enhancing the operational efficiency of all or a part of the buttons on a device requiring the use of buttons,
a method of enhancing the efficiency of the buttons on electric and electronic devices that have the following distinctive feature:
the carrying out of an operation designated in advance based on a combination situation that includes the combination, combination sequence, or the method of hitting the button of two or more buttons that are simultaneously in the state of being switched on, and
the designation of two or more combination-inducing-buttons that bring on the same designated operation for the purpose of inducing the same designated operation even when a certain combination-inducing-button is combined by alternating with another combination-inducing-button that brings on the same designated operation.

97. In terms of claim 96
a method of enhancing the efficiency of the buttons on electric and electronic devices that have the following distinctive feature:
an operation brought on by above combination-inducing-button does not change depending on the relationship of spatial position with another button and instead is always designated in the same way irrespective of the relationship of spatial position with another button.

98. In terms of claim 96 or claim 97,
in the case where a letter button that has more than 2 letters allocated to it exists in the same letter input mode,
a method of enhancing the efficiency of the buttons on electric and electronic devices that have the following distinctive feature:
in a situation where a given button is switched on and another letter button is switched on later, one uses the button that has been switched on first as the above combination-inducing-button in order to allow one to type a letter of a sequence that has been selected from among the letters allocated to another letter button which was entered later.

99. In terms of claim 96 or claim 97
in the case where a letter button that has more than 2 letters allocated to it exists in the same letter mode,
a method of enhancing the efficiency of the buttons on electric and electronic devices that have the following distinctive feature:
in a situation where a letter button is switched on and another button is switched on later, one uses another button that has been switched on later as the above combination-inducing-button in order to allow the user to type a letter of a sequence that has been selected from among the letters allocated to the letter button that was switched on first.

100. In reference to claim 96,
In reference to the method of enhancing the operational efficiency of buttons on devices that contain a letter button to which two or more letters are allocated in the same letter mode and that require the use of buttons for operation,
if another letter button switches on while a certain letter button is switched on in the letter mode,
in respect to the user designating a combination-inducing-button which allows a letter button that is switched on first to type the letter of designated sequence allocated to a letter button switched on later or a letter button that is switched on later to type the letter of designated sequence allocated to a letter button switched on first,
a method of enhancing the efficiency of the buttons on electric and electronic devices that have the following distinctive feature:
the designating of two or more combination-inducing-buttons that permit the typing of the letter of the same designated sequence.

101. In reference to claim 100,
a method of enhancing the efficiency of the buttons on electric and electronic devices that have the following distinctive feature:
the operation brought on by above combination-inducing-button does not change depending on the relationship of spatial position with another button and instead is always designated in the same way irrespective of the relationship of spatial position with another button.

102. In reference to claim 100,
In reference to the method of enhancing the operational efficiency of buttons on devices that contain a letter button to which two or more letters are allocated in the same letter mode and that require the use of buttons for operation,
if another letter button switches on while a certain letter button is turned on in the letter mode,
one designates that a random button no. 1 and button no. 2 be included as combination-inducing-buttons which allow a letter button that switches on first to type the second letter allocated to the letter button that switches on later or a letter button that switches on later to type the second letter allocated to the letter button that switches on first,
And, from among the buttons excluding the abovementioned button no. 1 and button no. 2,
one designates that a random button no. 3 and button no. 4 be included as combination-inducing-buttons which allow a letter button that switches on first to type the third letter allocated to the letter button that switches on later or a letter button that switches on later to type the third letter allocated to the letter button that switches on first.
This entails the method of enhancing the efficiency of buttons on electric and electronic devices that have the above distinctive feature.

103. In terms of claim 102,
a method of enhancing the efficiency of the buttons on electric and electronic devices that have the following distinctive feature:
Including the number of cases where the abovementioned buttons from no. 1 to no. 4 are allocated as table below.
An Allocation Table for Relevant
Representative Letters

| | | | | | Recom- | Utilization |
|---|---|---|---|---|---|---|
| Number of | Button | Button | Button | Button | mendation | Row and |
| Cases | No. 1 | No. 2 | No. 3 | No. 4 | Rank | Column |
| 1 | 1 | 3 | 4 | 6 | 1 | 147* |
| 2 | 1 | 3 | 7 | 9 | | column |
| 3 | 1 | 3 | * | # | | 369# |
| 4 | 4 | 6 | 1 | 3 | | column |
| 5 | 4 | 6 | 7 | 9 | 2 | |
| 6 | 4 | 6 | * | # | | |
| 7 | 7 | 9 | 1 | 3 | | |
| 8 | 7 | 9 | 4 | 6 | | |
| 9 | 7 | 9 | * | # | 3 | |
| 10 | * | # | 1 | 3 | | |
| 11 | * | # | 4 | 6 | | |
| 12 | * | # | 7 | 9 | | |
| 13 | 1 | 2 | 4 | 5 | | 147* |
| 14 | 1 | 2 | 7 | 8 | | column |
| 15 | 1 | 2 | * | 0 | | 2580 |
| 16 | 4 | 5 | 1 | 2 | | column |
| 17 | 4 | 5 | 7 | 8 | | |
| 18 | 4 | 5 | * | 0 | | |
| 19 | 7 | 8 | 1 | 2 | | |
| 20 | 7 | 8 | 4 | 5 | | |
| 21 | 7 | 8 | * | 0 | | |
| 22 | * | 0 | 1 | 2 | | |
| 23 | * | 0 | 4 | 5 | | |
| 24 | * | 0 | 7 | 8 | | |
| 25 | 2 | 3 | 5 | 6 | | 2580 |
| 26 | 2 | 3 | 8 | 9 | | column |
| 27 | 2 | 3 | 0 | # | | 369# |
| 28 | 5 | 6 | 2 | 3 | | column |
| 29 | 5 | 6 | 8 | 9 | | |
| 30 | 5 | 6 | 0 | # | | |
| 31 | 8 | 9 | 2 | 3 | | |
| 32 | 8 | 9 | 5 | 6 | | |
| 33 | 8 | 9 | 0 | # | | |
| 34 | 0 | # | 2 | 3 | | |
| 35 | 0 | # | 5 | 6 | | |
| 36 | 0 | # | 8 | 9 | | |
| 37 | 1 | 4 | 2 | 5 | | 123 row |
| 38 | 1 | 4 | 3 | 6 | | 456 row |
| 39 | 2 | 5 | 1 | 4 | | |
| 40 | 2 | 5 | 3 | 6 | | |
| 41 | 3 | 6 | 1 | 4 | | |
| 42 | 3 | 6 | 2 | 5 | | |
| 43 | 1 | 7 | 2 | 8 | | 123 row |
| 44 | 1 | 7 | 3 | 9 | | 789 row |
| 45 | 2 | 8 | 1 | 7 | | |
| 46 | 2 | 8 | 3 | 9 | | |
| 47 | 3 | 9 | 1 | 7 | | |
| 48 | 3 | 9 | 2 | 8 | | |
| 49 | 1 | * | 2 | 0 | | 123 row |
| 50 | 1 | * | 3 | # | | *0# row |
| 51 | 2 | 0 | 1 | * | | |
| 52 | 2 | 0 | 3 | # | | |
| 53 | 3 | # | 1 | * | | |
| 54 | 3 | # | 2 | 0 | | |
| 55 | 4 | 7 | 5 | 8 | | 456 row |
| 56 | 4 | 7 | 6 | 9 | | 789 row |
| 57 | 5 | 8 | 4 | 7 | | |
| 58 | 5 | 8 | 6 | 9 | | |
| 59 | 6 | 9 | 4 | 7 | | |
| 60 | 6 | 9 | 5 | 8 | | |
| 61 | 4 | * | 5 | 0 | | 456 row |
| 62 | 4 | * | 6 | # | | *0# row |
| 63 | 5 | 0 | 4 | * | | |
| 64 | 5 | 0 | 6 | # | | |
| 65 | 6 | # | 4 | * | | |
| 66 | 6 | # | 5 | 0 | | |
| 67 | 7 | * | 8 | 0 | | 789 row |
| 68 | 7 | * | 9 | # | | *0# row |
| 69 | 8 | 0 | 7 | * | | |
| 70 | 8 | 0 | 9 | # | | |
| 71 | 9 | # | 7 | * | | |
| 72 | 9 | # | 8 | 0 | | |

104. In terms of claim 102,
from among the buttons excluding the abovementioned button no. 1 to button no. 4,
one designates that a random button no. 5 and button no. 6 be included as combination-inducing-buttons which allow a letter button that switches on first to type the fourth letter allocated to the letter button that switches on later or a letter button that switches on later to type the fourth letter allocated to the letter button that switches on first.
This entails the method of enhancing the efficiency of buttons on electric and electronic devices that have the above distinctive feature.

105. In terms of claim 104,
a method of enhancing the efficiency of the buttons on electric and electronic devices that have the following distinctive feature:
Including the number of cases where the abovementioned button from no. 1 to button no. 6 are allocated as table below
An Allocation Table for Relevant
Representative Letters

| | | | | | | | | Utilization |
|---|---|---|---|---|---|---|---|---|
| Number of | Button | Button | Button | Button | Button | Button | Recommendation | Row and |
| Cases | No. 1 | No. 2 | No. 3 | No. 4 | No. 5 | No. 6 | Rank | Column |
| 1 | 1 | 3 | 4 | 6 | 7 | 9 | 1 | 147* |
| 2 | 1 | 3 | 4 | 6 | * | # | 2 | column |
| 3 | 1 | 3 | 7 | 9 | 4 | 6 | | 369# |
| 4 | 1 | 3 | 7 | 9 | * | # | | column |
| 5 | 1 | 3 | * | # | 4 | 6 | | |
| 6 | 1 | 3 | * | # | 7 | 9 | | |
| 7 | 4 | 6 | 1 | 3 | 7 | 9 | | |
| 8 | 4 | 6 | 1 | 3 | * | # | | |
| 9 | 4 | 6 | 7 | 9 | 1 | 3 | | |
| 10 | 4 | 6 | 7 | 9 | * | # | 3 | |
| 11 | 4 | 6 | * | # | 1 | 3 | | |
| 12 | 4 | 6 | * | # | 7 | 9 | | |
| 13 | 7 | 9 | 1 | 3 | 4 | 6 | | |
| 14 | 7 | 9 | 1 | 3 | * | # | | |
| 15 | 7 | 9 | 4 | 6 | 1 | 3 | | |
| 16 | 7 | 9 | 4 | 6 | * | # | | |
| 17 | 7 | 9 | * | # | 1 | 3 | | |
| 18 | 7 | 9 | * | # | 4 | 6 | | |
| 19 | * | # | 1 | 3 | 4 | 6 | | |
| 20 | * | # | 1 | 3 | 7 | 9 | | |
| 21 | * | # | 4 | 6 | 1 | 3 | | |
| 22 | * | # | 4 | 6 | 7 | 9 | | |
| 23 | * | # | 7 | 9 | 1 | 3 | | |
| 24 | * | # | 7 | 9 | 4 | 6 | | |
| 25 | 1 | 2 | 4 | 5 | 7 | 8 | | 147* |
| 26 | 1 | 2 | 4 | 5 | * | 0 | | column |
| 27 | 1 | 2 | 7 | 8 | 4 | 5 | | 2580 |
| 28 | 1 | 2 | 7 | 8 | * | 0 | | column |
| 29 | 1 | 2 | * | 0 | 4 | 5 | | |
| 30 | 1 | 2 | * | 0 | 7 | 8 | | |
| 31 | 4 | 5 | 1 | 2 | 7 | 8 | | |
| 32 | 4 | 5 | 1 | 2 | * | 0 | | |
| 33 | 4 | 5 | 7 | 8 | 1 | 2 | | |
| 34 | 4 | 5 | 7 | 8 | * | 0 | | |
| 35 | 4 | 5 | * | 0 | 1 | 2 | | |
| 36 | 4 | 5 | * | 0 | 7 | 8 | | |
| 37 | 7 | 8 | 1 | 2 | 4 | 5 | | |
| 38 | 7 | 8 | 1 | 2 | * | 0 | | |
| 39 | 7 | 8 | 4 | 5 | 1 | 2 | | |
| 40 | 7 | 8 | 4 | 5 | * | 0 | | |
| 41 | 7 | 8 | * | 0 | 4 | 5 | | |
| 42 | 7 | 8 | * | 0 | 1 | 2 | | |
| 43 | * | 0 | 1 | 2 | 4 | 5 | | |
| 44 | * | 0 | 1 | 2 | 7 | 8 | | |
| 45 | * | 0 | 4 | 5 | 1 | 2 | | |
| 46 | * | 0 | 4 | 5 | 7 | 8 | | |
| 47 | * | 0 | 7 | 8 | 1 | 2 | | |
| 48 | * | 0 | 7 | 8 | 4 | 5 | | |
| 49 | 2 | 3 | 5 | 6 | 8 | 9 | | 2580 |
| 50 | 2 | 3 | 5 | 6 | 0 | # | | column |
| 51 | 2 | 3 | 8 | 9 | 5 | 6 | | 369# |
| 52 | 2 | 3 | 8 | 9 | 0 | # | | column |
| 53 | 2 | 3 | 0 | # | 5 | 6 | | |
| 54 | 2 | 3 | 0 | # | 8 | 9 | | |
| 55 | 5 | 6 | 2 | 3 | 8 | 9 | | |
| 56 | 5 | 6 | 2 | 3 | 0 | # | | |
| 57 | 5 | 6 | 8 | 9 | 2 | 3 | | |
| 58 | 5 | 6 | 8 | 9 | 0 | # | | |
| 59 | 5 | 6 | 0 | # | 2 | 3 | | |
| 60 | 5 | 6 | 0 | # | 8 | 9 | | |
| 61 | 8 | 9 | 2 | 3 | 5 | 6 | | |
| 62 | 8 | 9 | 2 | 3 | 0 | # | | |
| 63 | 8 | 9 | 5 | 6 | 2 | 3 | | |
| 64 | 8 | 9 | 5 | 6 | 0 | # | | |
| 65 | 8 | 9 | 0 | # | 2 | 3 | | |
| 66 | 8 | 9 | 0 | # | 5 | 6 | | |
| 67 | 0 | # | 2 | 3 | 5 | 6 | | |
| 68 | 0 | # | 2 | 3 | 8 | 9 | | |
| 69 | 0 | # | 5 | 6 | 2 | 3 | | |
| 70 | 0 | # | 5 | 6 | 8 | 9 | | |
| 71 | 0 | # | 8 | 9 | 2 | 3 | | |
| 72 | 0 | # | 8 | 9 | 5 | 6 | | |
| 73 | 1 | 4 | 2 | 5 | 3 | 6 | | 123 row |
| 74 | 1 | 4 | 3 | 6 | 2 | 5 | | 456 row |
| 75 | 2 | 5 | 1 | 4 | 3 | 6 | | |
| 76 | 2 | 5 | 3 | 6 | 1 | 4 | | |
| 77 | 3 | 6 | 1 | 4 | 2 | 5 | | |
| 78 | 3 | 6 | 2 | 5 | 1 | 4 | | |
| 79 | 1 | 7 | 2 | 8 | 3 | 9 | | 123 row |
| 80 | 1 | 7 | 3 | 9 | 2 | 8 | | 789 row |
| 81 | 2 | 8 | 1 | 7 | 3 | 9 | | |
| 82 | 2 | 8 | 3 | 9 | 1 | 7 | | |
| 83 | 3 | 9 | 1 | 7 | 2 | 8 | | |
| 84 | 3 | 9 | 2 | 8 | 1 | 7 | | |
| 85 | 1 | * | 2 | 0 | 3 | # | | 123 row |
| 86 | 1 | * | 3 | # | 2 | 0 | | *0# row |
| 87 | 2 | 0 | 1 | * | 3 | # | | |
| 88 | 2 | 0 | 3 | # | 1 | * | | |
| 89 | 3 | # | 1 | * | 2 | 0 | | |
| 90 | 3 | # | 2 | 0 | 1 | * | | |
| 91 | 4 | 7 | 5 | 8 | 6 | 9 | | 456 row |
| 92 | 4 | 7 | 6 | 9 | 5 | 8 | | 789 row |
| 93 | 5 | 8 | 4 | 7 | 6 | 9 | | |
| 94 | 5 | 8 | 6 | 9 | 4 | 7 | | |
| 95 | 6 | 9 | 4 | 7 | 5 | 8 | | |
| 96 | 6 | 9 | 5 | 8 | 4 | 7 | | |
| 97 | 4 | * | 5 | 0 | 6 | # | | 456 row |
| 98 | 4 | * | 6 | # | 5 | 0 | | *0# row |
| 99 | 5 | 0 | 4 | * | 6 | # | | |
| 100 | 5 | 0 | 6 | # | 4 | * | | |
| 101 | 6 | # | 4 | * | 5 | 0 | | |
| 102 | 6 | # | 5 | 0 | 4 | * | | |
| 103 | 7 | * | 8 | 0 | 9 | # | | 789 row |
| 104 | 7 | * | 9 | # | 8 | 0 | | *0# row |
| 105 | 8 | 0 | 7 | * | 9 | # | | |
| 106 | 8 | 0 | 9 | # | 7 | * | | |
| 107 | 9 | # | 7 | * | 8 | 0 | | |
| 108 | 9 | # | 8 | 0 | 7 | * | | |

106. In terms of claim 100,
In reference to the method of enhancing the operational efficiency of buttons on devices that contain a letter button to which two or more letters are allocated in the same letter mode and that require the use of buttons for operation,
if another letter button switches on while a certain letter button is switched on in the letter mode,
one designates that a random button no. 1 and button no. 2 be included as combination-inducing-buttons which allow a letter button that switches on first to type the first letter allocated to the letter button that switches on later or a letter button that switches on later to type the first letter allocated to the letter button that switches on first, And
from among the buttons excluding the abovementioned button no. 1 and button no. 2,
one designates that a random button no. 3 and button no. 4 be included as combination-inducing-buttons which allow a letter button that switches on first to type the second letter allocated to the letter button that switches on later or a letter button that switches on later to type the second letter allocated to the letter button that switches on first, and
from among the buttons excluding the abovementioned button no. 1 to button no. 4,
one designates that a random button no. 5 and button no. 6 be included as combination-inducing-buttons which allow a letter button that switches on first to type the third letter allocated to the letter button that switches on later or a letter button that switches on later to type the third letter allocated to the letter button that switches on first.
This entails the method of enhancing the efficiency of buttons on electric and electronic devices that have the above distinctive feature.

107. In terms of claim 106,
a method of enhancing the efficiency of the buttons on electric and electronic devices that have the following distinctive feature:
including the number of cases where the abovementioned button from no. 1 to no. 6 are allocated as table shown in claim 105.

108. In terms of claim 100,
In reference to the method of enhancing the operational efficiency of buttons on devices that contain a letter button to which two or more letters are allocated in the same letter mode and that require the use of buttons for operation,
if another letter button switches on while a certain letter button is switched on in the letter mode,
one designates that a random button no. 1 and button no. 2 be included as combination-inducing-buttons which allow a letter button that switches on first to type the first letter allocated to the letter button that switches on later or a letter button that switches on later to type the first letter allocated to a letter button that switches on first.
And
from among the buttons excluding the abovementioned button no. 1 and button no. 2,
one designates that a random button no. 3 and button no. 4 be included as combination-inducing-buttons which allow a letter button that switches on first to type the second letter allocated to the letter button that switches on later or a letter button that switches on later to type the second letter allocated to the letter button that switches on first, and
from among the buttons excluding the abovementioned button no. 1 to button no. 4,
one designates that a random button no. 5 and button no. 6 be included as combination-inducing-buttons which allow a letter button that switches on first to type the third letter allocated to the letter button that switches on later or a letter button that switches on later to type the third letter allocated to the letter button that switches on first, and
from among the buttons excluding the abovementioned button no. 1 to button no. 6,
one designates that a random button no. 7 and button no. 8 be included as combination-inducing-buttons which allow a letter button that switches on first to type the fourth letter allocated to the letter button that switches on later or a letter button that switches on later to type the fourth letter allocated to the letter button that switches on first.
This entails the method of enhancing the efficiency of buttons on electric and electronic devices that have the above distinctive feature.

109. In terms of claim 108,
a method of enhancing the efficiency of the buttons on electric and electronic devices that have the following distinctive feature:
Including the number of cases where the abovementioned button from no. 1 to no. 8 are allocated as table below.
An Allocation Table for Relevant
Representative Letters

| | | | | | | | | | | Utilization |
|---|---|---|---|---|---|---|---|---|---|---|
| Number of | Button | Button | Button | Button | Button | Button | Button | Button | Recommendation | Row and |
| Cases | No. 1 | No. 2 | No. 3 | No. 4 | No. 5 | No. 6 | No. 7 | No. 8 | Rank | Column |
| 1 | 1 | 3 | 4 | 6 | 7 | 9 | * | # | 1 | 147* |
| 2 | 1 | 3 | 4 | 6 | * | # | 7 | 9 | 2 | column |
| 3 | 1 | 3 | 7 | 9 | 4 | 6 | * | # | | 369# |
| 4 | 1 | 3 | 7 | 9 | * | # | 4 | 6 | | column |
| 5 | 1 | 3 | * | # | 4 | 6 | 7 | 9 | | |
| 6 | 1 | 3 | * | # | 7 | 9 | 4 | 6 | | |
| 7 | 4 | 6 | 1 | 3 | 7 | 9 | * | # | | |
| 8 | 4 | 6 | 1 | 3 | * | # | 7 | 9 | | |
| 9 | 4 | 6 | 7 | 9 | 1 | 3 | * | # | | |
| 10 | 4 | 6 | 7 | 9 | * | # | 1 | 3 | 3 | |
| 11 | 4 | 6 | * | # | 1 | 3 | 7 | 9 | | |
| 12 | 4 | 6 | * | # | 7 | 9 | 1 | 3 | | |
| 13 | 7 | 9 | 1 | 3 | 4 | 6 | * | # | | |
| 14 | 7 | 9 | 1 | 3 | * | # | 4 | 6 | | |
| 15 | 7 | 9 | 4 | 6 | 1 | 3 | * | # | | |
| 16 | 7 | 9 | 4 | 6 | * | # | 1 | 3 | | |
| 17 | 7 | 9 | * | # | 1 | 3 | 4 | 6 | | |
| 18 | 7 | 9 | * | # | 4 | 6 | 1 | 3 | | |
| 19 | * | # | 1 | 3 | 4 | 6 | 7 | 9 | | |
| 20 | * | # | 1 | 3 | 7 | 9 | 4 | 6 | | |
| 21 | * | # | 4 | 6 | 1 | 3 | 7 | 9 | | |
| 22 | * | # | 4 | 6 | 7 | 9 | 1 | 3 | | |
| 23 | * | # | 7 | 9 | 1 | 3 | 4 | 6 | | |
| 24 | * | # | 7 | 9 | 4 | 6 | 1 | 3 | | |
| 25 | 1 | 2 | 4 | 5 | 7 | 8 | * | 0 | | 147* |
| 26 | 1 | 2 | 4 | 5 | * | 0 | 7 | 8 | | column |
| 27 | 1 | 2 | 7 | 8 | 4 | 5 | * | 0 | | 2580 |
| 28 | 1 | 2 | 7 | 8 | * | 0 | 4 | 5 | | column |
| 29 | 1 | 2 | * | 0 | 4 | 5 | 7 | 8 | | |
| 30 | 1 | 2 | * | 0 | 7 | 8 | 4 | 5 | | |
| 31 | 4 | 5 | 1 | 2 | 7 | 8 | * | 0 | | |
| 32 | 4 | 5 | 1 | 2 | * | 0 | 7 | 8 | | |
| 33 | 4 | 5 | 7 | 8 | 1 | 2 | * | 0 | | |
| 34 | 4 | 5 | 7 | 8 | * | 0 | 1 | 2 | | |
| 35 | 4 | 5 | * | 0 | 1 | 2 | 7 | 8 | | |
| 36 | 4 | 5 | * | 0 | 7 | 8 | 1 | 2 | | |
| 37 | 7 | 8 | 1 | 2 | 4 | 5 | * | 0 | | |
| 38 | 7 | 8 | 1 | 2 | * | 0 | 4 | 5 | | |
| 39 | 7 | 8 | 4 | 5 | 1 | 2 | * | 0 | | |
| 40 | 7 | 8 | 4 | 5 | * | 0 | 1 | 2 | | |
| 41 | 7 | 8 | * | 0 | 4 | 5 | 1 | 2 | | |
| 42 | 7 | 8 | * | 0 | 1 | 2 | 4 | 5 | | |
| 43 | * | 0 | 1 | 2 | 4 | 5 | 7 | 8 | | |
| 44 | * | 0 | 1 | 2 | 7 | 8 | 4 | 5 | | |
| 45 | * | 0 | 4 | 5 | 1 | 2 | 7 | 8 | | |
| 46 | * | 0 | 4 | 5 | 7 | 8 | 1 | 2 | | |
| 47 | * | 0 | 7 | 8 | 1 | 2 | 4 | 5 | | |
| 48 | * | 0 | 7 | 8 | 4 | 5 | 1 | 2 | | |
| 49 | 2 | 3 | 5 | 6 | 8 | 9 | 0 | # | | 2580 |
| 50 | 2 | 3 | 5 | 6 | 0 | # | 8 | 9 | | column |
| 51 | 2 | 3 | 8 | 9 | 5 | 6 | 0 | # | | 369# |
| 52 | 2 | 3 | 8 | 9 | 0 | # | 5 | 6 | | column |
| 53 | 2 | 3 | 0 | # | 5 | 6 | 8 | 9 | | |
| 54 | 2 | 3 | 0 | # | 8 | 9 | 5 | 6 | | |
| 55 | 5 | 6 | 2 | 3 | 8 | 9 | 0 | # | | |
| 56 | 5 | 6 | 2 | 3 | 0 | # | 8 | 9 | | |
| 57 | 5 | 6 | 8 | 9 | 2 | 3 | 0 | # | | |
| 58 | 5 | 6 | 8 | 9 | 0 | # | 2 | 3 | | |
| 59 | 5 | 6 | 0 | # | 2 | 3 | 8 | 9 | | |
| 60 | 5 | 6 | 0 | # | 8 | 9 | 2 | 3 | | |
| 61 | 8 | 9 | 2 | 3 | 5 | 6 | 0 | # | | |
| 62 | 8 | 9 | 2 | 3 | 0 | # | 5 | 6 | | |
| 63 | 8 | 9 | 5 | 6 | 2 | 3 | 0 | # | | |
| 64 | 8 | 9 | 5 | 6 | 0 | # | 2 | 3 | | |
| 65 | 8 | 9 | 0 | # | 2 | 3 | 5 | 6 | | |
| 66 | 8 | 9 | 0 | # | 5 | 6 | 2 | 3 | | |
| 67 | 0 | # | 2 | 3 | 5 | 6 | 8 | 9 | | |
| 68 | 0 | # | 2 | 3 | 8 | 9 | 5 | 6 | | |
| 69 | 0 | # | 5 | 6 | 2 | 3 | 8 | 9 | | |
| 70 | 0 | # | 5 | 6 | 8 | 9 | 2 | 3 | | |
| 71 | 0 | # | 8 | 9 | 2 | 3 | 5 | 6 | | |
| 72 | 0 | # | 8 | 9 | 5 | 6 | 2 | 3 | | |

110. In terms of claim 108,
from among the buttons excluding the abovementioned button no. 1 to button no. 8,
one designates that a random button no. 9 and button no. 10 be included as combination-inducing-buttons which allow a letter button that switches on first to type the fifth letter allocated to the letter button that switches on later or a letter button that switches on later to type the fifth letter allocated to the letter button that switches on first, and
from among the buttons excluding the abovementioned button no. 1 to button no. 10,
one designates that a random button no. 11 and button no. 12 be included as combination-inducing-buttons which allow a letter button that switches on first to type the sixth letter allocated to the letter button that switches on later or a letter button that switches on later to type the sixth letter allocated to the letter button that switches on first.
This entails the method of enhancing the efficiency of buttons on electric and electronic devices that have the above distinctive feature.

111. In reference to the method of enhancing the operational efficiency of buttons on devices that contain a letter button to which two or more letters are allocated in the same letter mode and that require the use of buttons for operation,
one designates button 1 as a preceding or succeeding combination-inducing-button which allows the typing of the first letter allocated to each letter button, or
one designates button 2 as a preceding or succeeding combination-inducing-button which allows the typing of the second letter allocated to each letter button, or
one designates button 3 as a preceding or succeeding combination-inducing-button which allows the typing of the third letter allocated to each letter button, or
one designates button 4 as a preceding or succeeding combination-inducing-button which allows the typing of the fourth letter allocated to each letter button, or
one designates button 5 as a preceding or succeeding combination-inducing-button which allows the typing of the fifth letter allocated to each letter button, or
one designates button 6 as a preceding or succeeding combination-inducing-button which allows the typing of the sixth letter allocated to each letter button, or
one designates button 7 as a preceding or succeeding combination-inducing-button which allows the typing of the seventh letter allocated to each letter button, or
one designates button 8 as a preceding or succeeding combination-inducing-button which allows the typing of the eighth letter allocated to each letter button, or
one designates button 9 as a preceding or succeeding combination-inducing-button which allows the typing of the ninth letter allocated to each letter button, or
one designates button 0 as a preceding or succeeding combination-inducing-button which allows the typing of the 10th letter allocated to each letter button.
This entails the method of enhancing the efficiency of buttons on electric and electronic devices that have the above one of the distinctive feature.

112. In terms of claim 100,
In reference to the method of enhancing the operational efficiency of buttons on devices that contain a letter button to which two or more letters are allocated in the same letter mode and that require the use of buttons for operation,
a method of enhancing the efficiency of the buttons on electric and electronic devices that have the following distinctive feature:
the differentiating of the specific sequence of the letter that is allocated to a letter button and is typed when the combination-inducing-button either precedes or succeeds the letter button, in the case where one designates a button to which no letter is allocated as a combination-inducing-button that allows the typing of a specific sequence letter found on a button to which letters are allocated.

113. In reference to one of claims 102, 104, 106, 108 or 110,
one changes the function that allows the typing of the first letter as Operational Function No. 1 that allows for random designation, and
one changes the function that allows the typing of the second letter as Operational Function No. 2 that allows for random designation, and
one changes the function that allows the typing of the third letter as Operational Function No. 3 that allows for random designation, and
one changes the function that allows the typing of the fourth letter as Operational Function No. 4 that allows for random designation, and
one changes the function that allows the typing of the fifth letter as Operational Function No. 5 that allows for random designation, and
one changes the function that allows the typing of the sixth letter as Operational Function No. 6 that allows for random designation. And these are then altered according to a given context which enables that function to be designated.
This entails the method of enhancing the efficiency of buttons on electric and electronic devices that have the above distinctive feature.

114. In reference to one of claims 102, 104, 106, 108 or 110,
since the “which” in the phrase, “which sequence letter” allocated to a letter button can vary depending on the situation, the sequence of the printed letter allocated to a letter button, or the frequency of hitting the key corresponds to the letter when typing in using the multi tab method, or the number is not a consecutively increasing but a random figure.
This entails the method of enhancing the efficiency of buttons on electric and electronic devices that have the above distinctive feature.

115. In reference to one of the claims 96, 97, 100-110 or 111,
a method of enhancing the efficiency of the buttons on electric and electronic devices that have the following distinctive feature:
the recognition as combination the situation where the length of time between switching off the button that has been switched on first and switching on the button that was turned on latter is within the allotted amount.

116. In respect to the method of enhancing the operational efficiency of all or a part of the buttons on devices that require the use of buttons,
a method of enhancing the efficiency of the buttons on electric and electronic devices that have the following distinctive feature:
the allocation of at least one of either the left or right combination-inducing-button in the upper area of the keyboard.

117. a method of enhancing the efficiency of the buttons on electric and electronic devices that have the following distinctive feature:
the exchanging of places among the letter buttons part, direction buttons part, or supplementary number buttons part, in respect to keyboards that contain the letter buttons part, direction buttons part, and supplementary buttons part, as shown in FIG.

118. In terms of the method of enhancing the operational efficiency of all or a part of the buttons on devices that require the use of buttons,
a method of enhancing the efficiency of the buttons on electric and electronic devices that have the following distinctive feature:
the allocation of methods of hitting keys that differ from each other, including a single hit, double click, triple click, long press to each mode while leaving the toggle key as it is so that a signal for alteration of each mode is given, in terms of operation for alteration of modes corresponding to the one toggle key on the keyboard.
